(19) United States
(12) Patent Application Publication
(10) Pub. No.: US 2018/0081272 A1
(43) Pub. Date: Mar. 22, 2018

(54) THERMAL CROSSLINKING ACCELERATOR, POLYSILOXANE-CONTAINING RESIST UNDERLAYER FILM FORMING COMPOSITION CONTAINING SAME, AND PATTERNING PROCESS USING SAME

(71) Applicant: SHIN-ETSU CHEMICAL CO., LTD., Tokyo (JP)

(72) Inventors: Tsutomu OGIHARA, Jyoetsu-shi (JP); Yusuke BIYAJIMA, Jyoetsu-shi (JP); Hiroyuki URANO, Jyoetsu (JP)

(73) Assignee: SHIN-ETSU CHEMICAL CO., LTD., Toyko (JP)

(21) Appl. No.: 15/822,818

(22) Filed: Nov. 27, 2017

Related U.S. Application Data
(62) Division of application No. 14/142,412, filed on Dec. 27, 2013.

(30) Foreign Application Priority Data
Jan. 24, 2013 (JP) 2013-10814

(51) Int. Cl. G03F 7/09; G03F 7/00; G03F 7/075; G03F 7/32; C09D 183/04; H01L 21/311; H01L 21/308

(52) U.S. Cl. CPC G03F 7/094; G03F 7/0002; G03F 7/0752; G03F 7/325; H01L 21/3081; H01L 21/31116; H01L 21/31138; H01L 21/31144; C09D 183/04

(57) ABSTRACT

The present invention provides a thermal crosslinking accelerator that can improve an etching selectivity to the upper layer resist thereby improving the pattern form after etching even in a finer pattern than the case of using a conventional silicon-containing resist underlayer film. Thus, provided is a thermal crosslinking accelerator of a polysiloxane compound wherein the thermal crosslinking accelerator of a polysiloxane compound is shown by the following general formula (A-1),

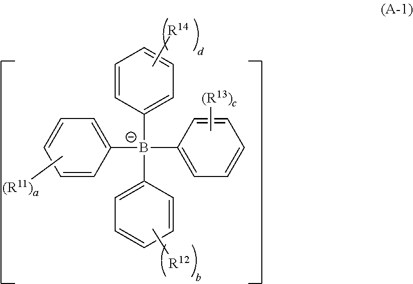

wherein R¹¹, R¹², R¹³, and R¹⁴ each represents a hydrogen atom, a halogen atom, a linear, a branched, a cyclic alkyl group or the like having 1 to 20 carbon atoms, an optionally substituted aryl group having 6 to 20 carbon atoms, or an aralkyl group or the like having 7 to 20 carbon atoms, wherein a part of or all of hydrogen atoms in these groups may be substituted by an alkoxy group or the like. “a”, “b”, “c”, and “d” represent an integer of 0 to 5; in the case that “a”, “b”, “c”, and “d” are 2 or more, R¹¹, R¹², R¹³, and R¹⁴ may form a cyclic structure. Character L represents lithium and the like.

### BACKGROUND OF THE INVENTION

### Field of the Invention

The present invention relates to a thermal crosslinking accelerator, to a polysiloxane-containing resist underlayer film forming composition containing this, and to a patterning process using this.

### Description of the Related Art

In 1980s, photo-exposure using a g-beam (436 nm) or an i-beam (365 nm) of a mercury lamp as a light source had been widely used in the resist patterning. As a means for further finer patterning, shifting to a shorter wavelength of the exposure light was assumed to be effective, so that, in mass production process after the DRAM (Dynamic Random Access Memory) with 64 megabits (processing dimension of 0.25 μm or less) in 1990s, a KrF excimer laser (248 nm), a shorter wavelength than the i-beam (365 nm), had been used in place of the i-beam as the exposure light source. However, in production of DRAMs with integration of 256 M and 1 G or higher which require further finer process technologies (processing dimension of 0.2 μm or less), a light source with further short wavelength is required, and thus, a photolithography using an ArF excimer laser (193 nm) has been investigated seriously since about a decade ago.

At first, the ArF lithography was planned to be applied to manufacturing of a device starting from a 180-nm node device, but the life of the KrF excimer lithography was prolonged to mass production of the 130-nm node device; and thus, a full-fledged application of the ArF lithography started from the 90-nm node. Further, mass production of the 65-nm node device is now underway by combining it with a lens having an increased NA till 0.9. Further shortening of wavelength of the exposure light is progressing for the next 45-nm node device; and the F₂-lithography with 157 nm wavelength became a candidate for it.

However, there are many problems in the F₂ lithography: cost-up of a scanner due to use of the large quantities of the expensive CaF₂ single crystal for a projection lens; extremely poor durability of a soft pellicle, which leads to change of an optical system due to introduction of a hard pellicle; decrease in etching resistance of a resist film, and so forth. Because of these problems, development of the F₂ lithography was suspended, and the ArF immersion lithography was introduced.

In the ArF immersion lithography, water having refractive index of 1.44 is introduced between a projection lens and a wafer by a partial fill method thereby enabling high speed scanning; and thus, mass production of the 45-nm node device is now underway by using a lens with a NA class of 1.3.

For the 32-nm node lithography technology, lithography with a vacuum ultraviolet beam (EUV) of 13.5 nm wavelength is considered to be a candidate. Problems to be solved in the EUV lithography are to obtain a higher output power of the laser, a higher sensitivity of the resist film, a higher resolution power, a lower line edge roughness (LER), a non-defect MoSi laminate mask, a lower aberration of the reflective mirror, and so forth; and thus, there are innumerable problems to be solved.

Development of the immersion lithography with a high refractive index, another candidate for the 32-nm node, was suspended, because transmittance of LUAG, a candidate for a high refractive index lens, is low, and refractive index of the liquid could not reach an aimed value of 1.8.

As mentioned above, in the photo-exposure used as a general technology, resolution power based on the wavelength of a light source is approaching to its inherent limit. Accordingly, in recent years, an organic solvent development in which a very fine hole pattern, which cannot be achieved by a patterning process using a positive tone based on a conventional alkaline development, is formed by a negative tone based on an organic solvent development is receiving an attention again. This is the patterning process in that a negative pattern is formed by an organic solvent development using a positive resist composition having a high resolution power. In addition, a study to obtain a doubled resolution power by combining two developments of the alkaline development and the organic solvent development is going on (Patent Document 1 to 3).

As one method to transfer a lithography pattern to a substrate based on the idea as mentioned above, a multilayer resist method may be mentioned. In this method, an intermediate film having different etching selectivity to a photoresist film, i.e., a resist upper layer film, for example, a silicon-containing resist underlayer film, is interposed between the resist upper layer film and a substrate to be processed, and then, after a pattern is formed on the resist upper layer film, this pattern is transferred by dry etching to the resist underlayer film by using the upper layer resist pattern as a dry etching mask, and further, the pattern is transferred by dry etching to the substrate to be processed by using the resist underlayer film as a dry etching mask.

A silicon-containing film forming composition is well known as the composition that may be used in the multilayer resist method as mentioned above. For example, a SiO₂ film (Patent Document 4) and a SiON film (Patent Document 5) may be mentioned as the example of the silicon-containing inorganic film by a CVD method; and a SOG (spin-on-glass) film (Patent Document 6) and a crosslinkable silsesquioxane film (Patent Document 7) may be mentioned as the example by a spin coating method.

### PRIOR ART DOCUMENTS

### Patent Documents

### Patent Document 1: Japanese Patent Laid-Open Publication No. 2008-281974

### Patent Document 2: Japanese Patent Laid-Open Publication No. 2008-281980

### Patent Document 3: Japanese Patent Laid-Open Publication No. 2009-53657

Patent Document 4: Japanese Patent Laid-Open Publication No. H07-183194
Patent Document 5: Japanese Patent Laid-Open Publication No. H07-181688

### Patent Document 6: Japanese Patent Laid-Open Publication No. 2007-302873

### Patent Document 7: Japanese Patent Laid-Open Publication No. 2005-520354

### SUMMARY OF THE INVENTION

Inventors of the present invention have carried out an extensive investigation on the lithography characteristics and stability of a silicon-containing resist underlayer film forming composition; and as a result, a silicon-containing resist underlayer film having excellent etching selectivity and storage stability could be provided by providing a silicon-containing resist underlayer film forming composition containing a thermal crosslinking accelerator such as those shown in Japanese Patent No. 4716037.

However, miniaturization of a semiconductor device is advancing further so that an upper layer resist becomes thinner in order not to cause collapse of an upper layer resist pattern. As a consequence of it, as the performance required for a resist underlayer film, requirement to improve an etching selectivity is increasing even in the upper layer resist pattern having thinner thickness than ever.

The present invention was carried out in view of the situation mentioned above; and thus, an object thereof is to provide a thermal crosslinking accelerator that can further improve an etching selectivity to the upper layer resist thereby improving the pattern form after etching even in a finer pattern than the case of using a conventional silicon-containing resist underlayer film.

The present invention was made to solve the problem mentioned above, and provides a thermal crosslinking accelerator of a polysilozane compound wherein the thermal crosslinking accelerator of a polysilozane compound is shown by the following general formula (A-1),

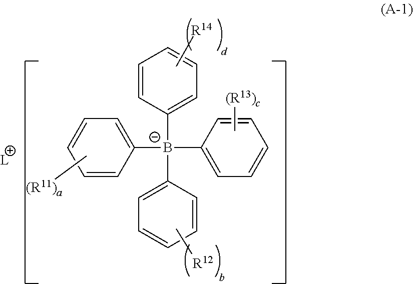

wherein R¹¹, R¹², R¹³, and R¹⁴ each represents a hydrogen atom, a halogen atom, a linear, a branched, or a cyclic alkyl, alkenyl, oxoalkyl, or oxoalkenyl group having 1 to 20 carbon atoms; an optionally substituted aryl group having 6 to 20 carbon atoms; or an aralkyl or an aryloxoalkyl group having 7 to 20 carbon atoms, wherein a part of or all of hydrogen atoms in these groups may be substituted by an alkoxy group, an amino group, an alkylamino group, a halogen atom, or a trimethylsilyl group. “a”, “b”, “c”, and “d” represent an integer of 0 to 5. In the case that “a”, “b”, “c”, and “d” are 2 or more, R¹¹, R¹², R¹³, and R¹⁴ may form a cyclic structure. Character L represents lithium, sodium, potassium, rubidium, cesium, or a counter ion shown by the following general formula (A-2), (A-3), (A-4), or (A-5),

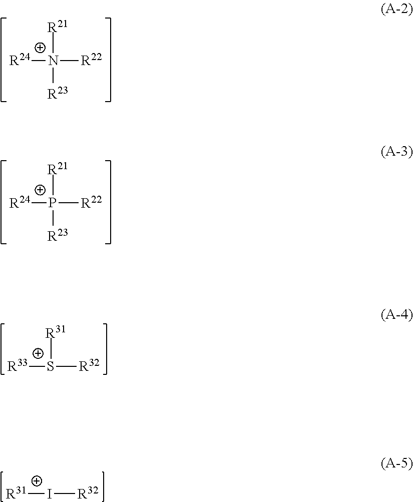

wherein R²¹, R²², R²³, and R²⁴ each represents a linear, a branched, or a cyclic alkyl, alkenyl, oxoalkyl, or oxoalkenyl group having 1 to 20 carbon atoms; an optionally substituted aryl group having 6 to 20 carbon atoms; or an aralkyl or an aryloxoalkyl group having 7 to 12 carbon atoms, wherein a part of or all of hydrogen atoms in these groups may be substituted by a halogen atom, an alkyl group, an alkoxy group, or a trimethylsilyl group. R²¹ and R²², and R²¹, R²², and R²³ may form a ring; and in the case of forming a ring, R²¹ and R²², and R²¹, R²², and R²³ represent an alkylene group having 3 to 10 carbon atoms. R³¹, R³², and R³³ represent the same meanings as R²¹, R²², R²³, and R²⁴, or they may be a hydrogen atom. R³² and R³³ may from a ring; and in the case of forming the ring, R³² and R³³ each represents an alkylene group having 1 to 6 carbon atoms.

When the thermal crosslinking accelerator like this is used, for example, in a polysiloxane-containing resist underlayer film, excellent adhesion with the photoresist pattern formed thereon can be obtained while showing high etching selectivity to both the resist pattern formed thereon and the film formed thereunder such as, for example, an organic film; and thus, a pattern can be transferred in a good pattern form when the formed photoresist pattern is transferred sequentially to the polysiloxane-containing resist underlayer film and then to the organic underlayer film by using a dry etching process. Accordingly, finally the pattern formed in the upper layer resist can be transferred to a substrate with high precision.

Further provided is a polysiloxane-containing resist underlayer film forming composition, wherein the thermal crosslinking accelerator of the present invention and a polysiloxane are contained therein.

The polysiloxane-containing resist underlayer film forming composition as mentioned above has excellent adhesion with the resist pattern formed on the polysiloxane-containing resist underlayer film while showing excellent dry etching selectivity between the photoresist film, which is the upper layer of the polysiloxane-containing resist underlayer film, and the film formed thereunder such as, for example, an organic film.

At this time, preferably the polysiloxane-containing resist underlayer film forming composition is characterized by that the polysiloxane contains one or more compound selected from the group consisting of a compound shown by the following general formula (B-1), a hydrolysate thereof, a condensate thereof, and a hydrolysis-condensate thereof,

R^{1B}_{B1}R^{2B}_{B2}R^{3B}_{B3}Si(OR^{0B})_{(4-B1-B2-B3)} (B-1)

wherein R^{0B} represents a hydrocarbon group having 1 to 6 carbon atoms; and R^{1B}, R^{2B}, and R^{3B} represent a hydrogen atom or a monovalent organic group. B1, B2, and B3 represent 0 or 1, and 0≦B1+B2+B3≦3.

The polysiloxane-containing resist underlayer film forming composition as mentioned above is preferable because the adhesion and the dry etching selectivity are enhanced further.

In addition, provided is a patterning process, wherein an organic underlayer film is formed on a body to be processed by using a coating-type organic underlayer film forming composition, on the organic underlayer film is formed a polysiloxane-containing resist underlayer film by using the polysiloxane-containing resist underlayer film forming composition of the present invention, on the polysiloxane-containing resist underlayer film is formed a resist pattern, the pattern is transferred by dry etching to the resist underlayer film by using the resist film having the formed pattern as a mask, the pattern is transferred by dry etching to the organic underlayer film by using the resist underlayer film having the transferred pattern as a mask, and further, the pattern is transferred by dry etching to the body to be processed by using the organic underlayer film having the transferred pattern as a mask.

Further in addition, provided is a patterning process, wherein an organic hard mask mainly comprising a carbon atom is formed on a body to be processed by using a CVD method, on the organic hard mask is formed a polysiloxane-containing resist underlayer film by using the polysiloxane-containing resist underlayer film forming composition of the present invention, on the polysiloxane-containing resist underlayer film is formed a resist pattern, the pattern is transferred by dry etching to the resist underlayer film by using the resist film having the formed pattern as a mask, the pattern is transferred by dry etching to the organic hard mask by using the resist underlayer film having the transferred pattern as a mask, and further, the pattern is transferred by dry etching to the body to be processed by using the organic hard mask having the transferred pattern as a mask.

The patterning process by the three-layer resist method using the composition of the present invention as mentioned above can form a fine pattern on the substrate with high precision.

Further at this time, the body to be processed is preferably a substrate for a semiconductor device, a metal film, a metal carbide film, a metal oxide film, a metal nitride film, a metal oxycarbide film, or a metal oxynitride film.

Further at this time, the metal to constitute the body to be processed is preferably silicon, titanium, tungsten, hafnium, zirconium, chromium, germanium, copper, aluminum, indium, gallium, arsenic, palladium, iron, tantalum, iridium, molybdenum, or an alloy of them.

Further at this time, it is preferable that the resist pattern is formed by a directed self-assembly method (DSA method) or a nanoimprinting lithography method.

The patterning process using the above-mentioned methods can form a further finer pattern on the substrate with high precision.

Further at this time, the resist pattern may be formed by a method that a photoresist film is formed by using a chemically amplified resist composition, the photoresist film is exposed by a high energy beam after heat treatment, and then an exposed part of the photoresist film is dissolved by using an alkaline developing solution to form a positive pattern.

Further at this time, the resist pattern may be formed by a method that a photoresist film is formed by using a chemically amplified resist composition, the photoresist film is exposed by a high energy beam after heat treatment, and then a unexposed part of the photoresist film is dissolved by using an organic solvent developing solution to form a negative pattern.

By using these methods, a fine positive pattern and a fine negative pattern may be formed with high precision.

Further at this time, the lithography method using the high energy beam is preferably a lithography method using a light having the wavelength of 300 nm or less, a lithography method using an EUV light, or an electron beam direct drawing method.

As mentioned above, the present invention is used the most preferably to form a fine pattern with high precision by the lithographies using the light having the wavelength of 300 nm or less.

When the thermal crosslinking accelerator of the polysiloxane compound according to the present invention is used, for example, in a polysiloxane-containing resist underlayer film, excellent adhesion with the photoresist pattern formed thereon can be obtained while showing high etching selectivity to both the resist pattern formed thereon and the film formed thereunder such as, for example, an organic film; and thus, a pattern can be transferred in a good pattern form when the formed photoresist pattern is transferred sequentially to the polysiloxane-containing resist underlayer film and then to the organic underlayer film by using a dry etching process. Accordingly, the pattern formed in the upper layer resist can be transferred to the substrate with high precision.

### DESCRIPTION OF THE PREFERRED EMBODIMENTS

Hereunder, the present invention will be explained in more detail, but the present invention is not limited to these descriptions.

The anionic part of the compound shown by the following general formula (A-1) which is used as the thermal crosslinking accelerator of the present invention is shown by the following structure (A-1a).

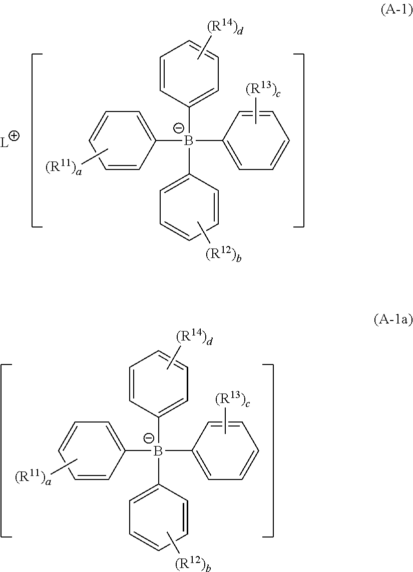

wherein R¹¹, R¹², R¹³, and R¹⁴ each represents a hydrogen atom, a halogen atom, a linear, a branched, or a cyclic alkyl, alkenyl, oxoalkyl, or oxoalkenyl group having 1 to 20 carbon atoms; an optionally substituted aryl group having 6 to 20 carbon atoms; or an aralkyl or an aryloxoalkyl group having 7 to 20 carbon atoms, wherein a part of or all of hydrogen atoms in these groups may be substituted by an alkoxy group, an amino group, an alkylamino group, a halogen atom, or a trimethylsilyl group. “a”, “b”, “c”, and “d” represent an integer of 0 to 5. In the case that “a”, “b”, “c”, and “d” are 2 or more, R¹¹, R¹², R¹³, and R¹⁴ may form a cyclic structure.

Specific example thereof includes the following structures.

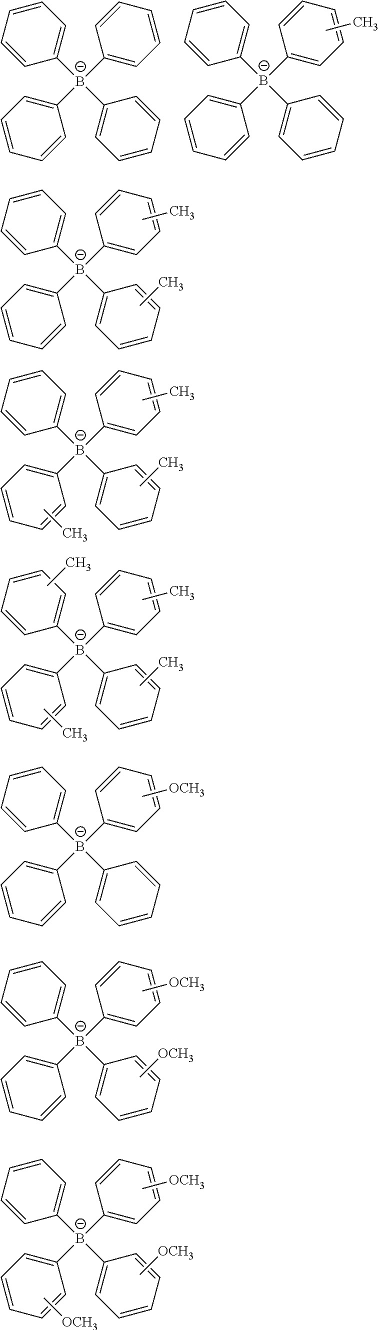

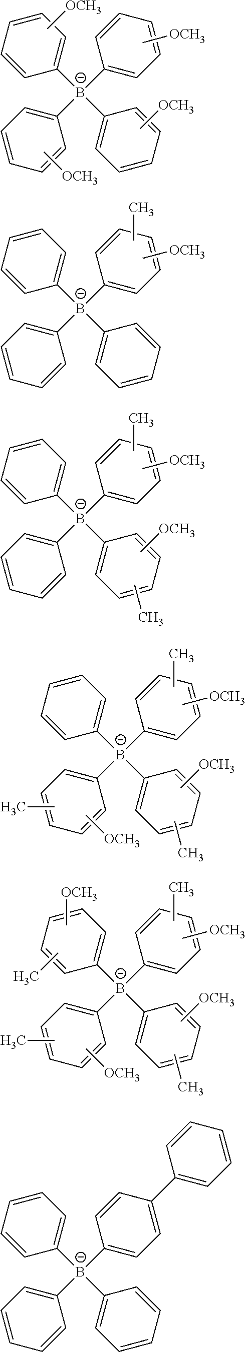

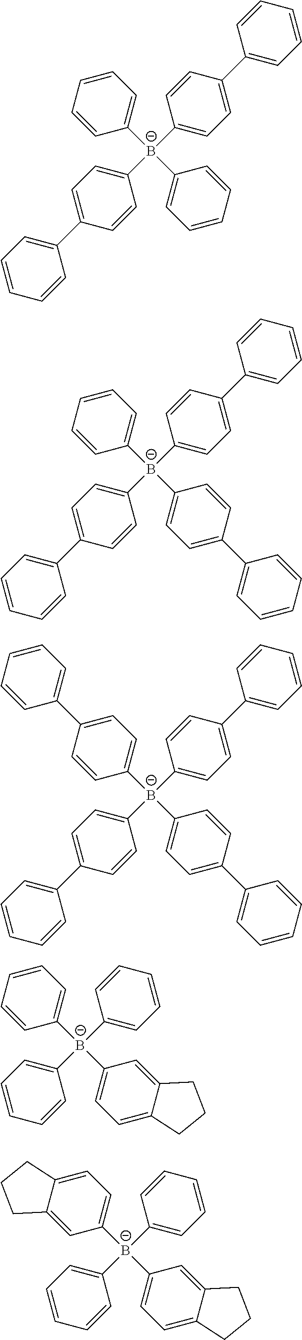 [SMILES: c1ccc(-c2ccc([B-](c3ccccc3)(c3ccccc3)c3ccc(-c4ccccc4)cc3)cc2)cc1 ; c1ccc(-c2ccc([B-](c3ccccc3)(c3ccc(-c4ccccc4)cc3)c3ccc(-c4ccccc4)cc3)cc2)cc1 ; c1ccc(-c2ccc([B-](c3ccc(-c4ccccc4)cc3)(c3ccc(-c4ccccc4)cc3)c3ccc(-c4ccccc4)cc3)cc2)cc1 ; c1ccc([B-](c2ccccc2)(c2ccccc2)c2ccc3c(c2)CCC3)cc1 ; c1ccc([B-](c2ccccc2)(c2ccc3c(c2)CCC3)c2ccc3c(c2)CCC3)cc1]

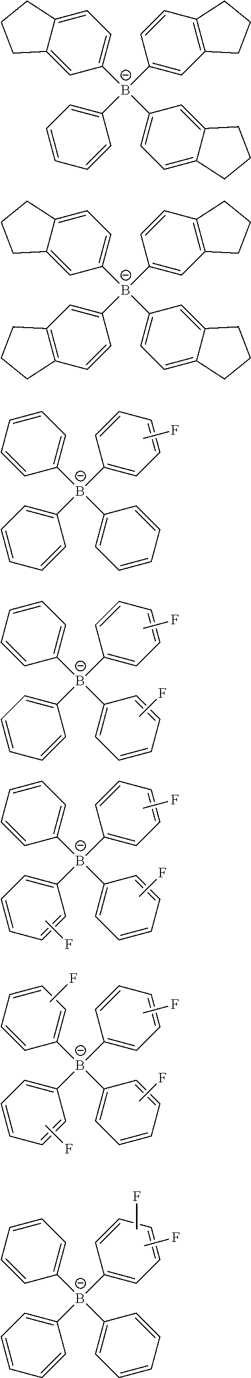

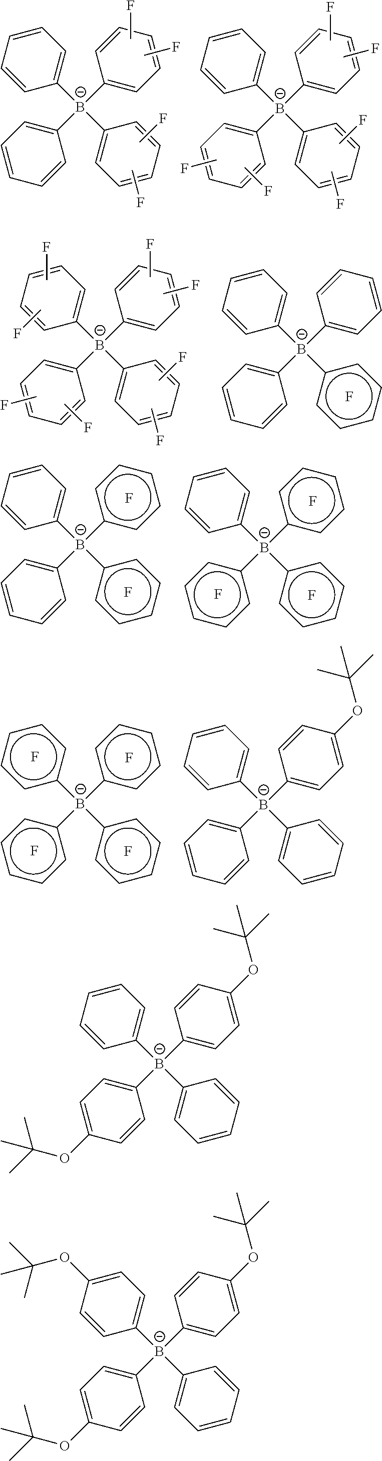

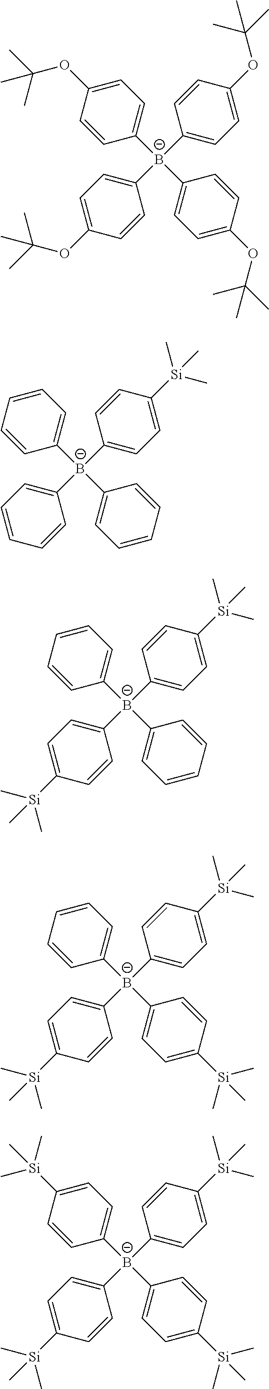

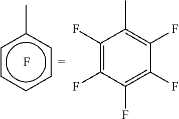

The cationic part of the compound shown by the general formula (A-1) is lithium, sodium, potassium, rubidium, cesium, or a counter ion shown by the following general formula (A-2), (A-3), (A-4), or (A-5).

As to (A-2), the structure shown below is used,

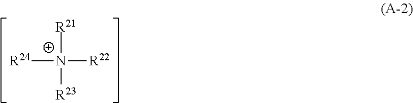

wherein R²¹, R²², R²³, and R²⁴ each represents a linear, a branched, or a cyclic alkyl, alkenyl, oxoalkyl, or oxoalkenyl group having 1 to 20 carbon atoms; an optionally substituted aryl group having 6 to 20 carbon atoms; or an aralkyl or an aryloxoalkyl group having 7 to 12 carbon atoms, wherein a part of or all of hydrogen atoms in these groups may be substituted by a halogen atom, an alkyl group, an alkoxy group, or a trimethylsilyl group. R²¹ and R²², and R²¹, R²², and R²³ may form a ring; and in the case of forming a ring, R²¹ and R²², and R²¹, R²², and R²³ represent an alkylene group having 3 to 10 carbon atoms.

Specific example thereof includes the following structures.

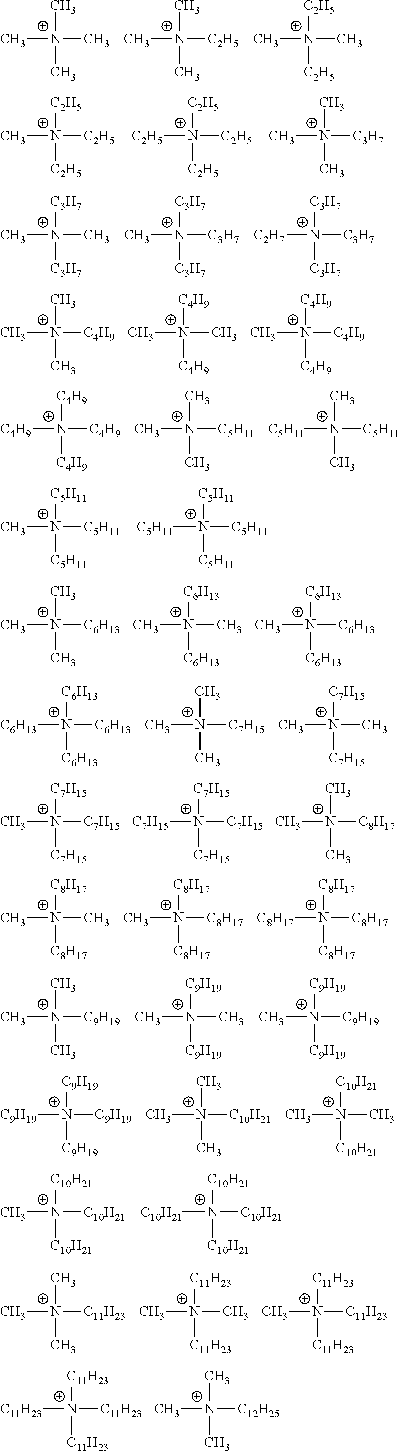

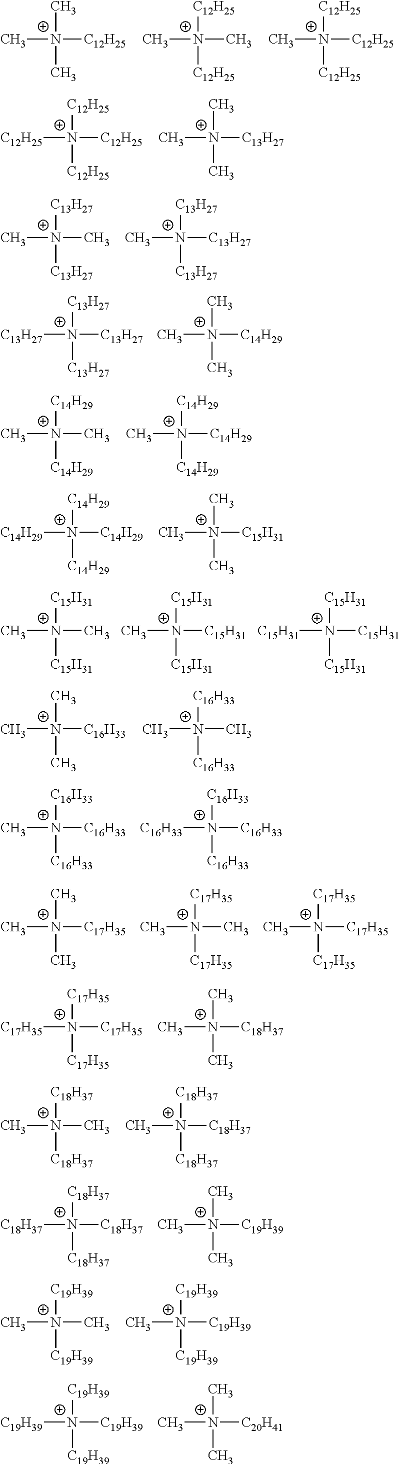

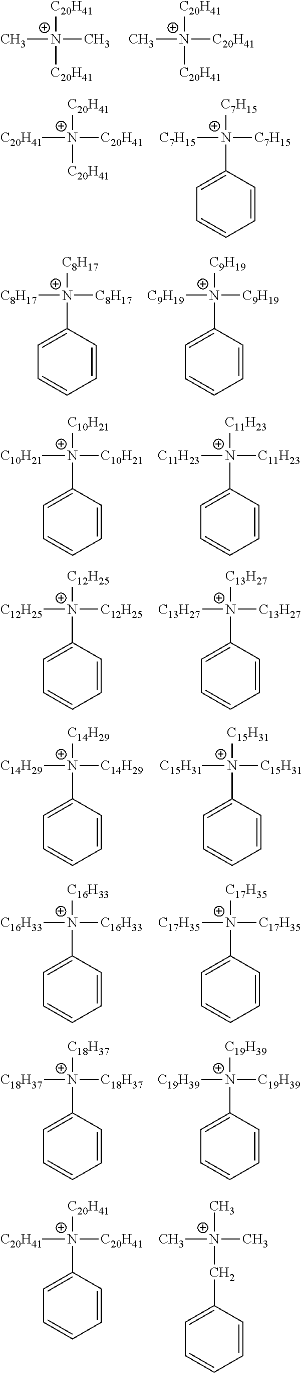

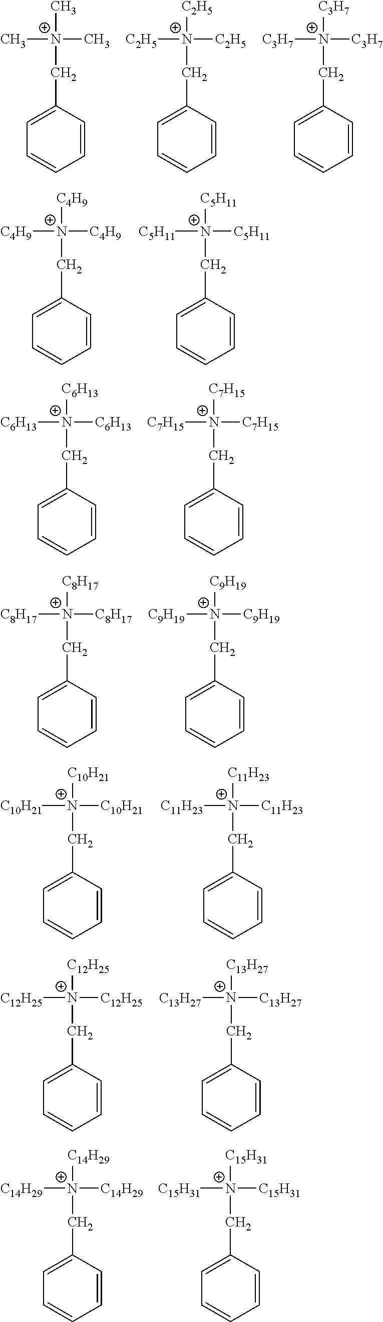

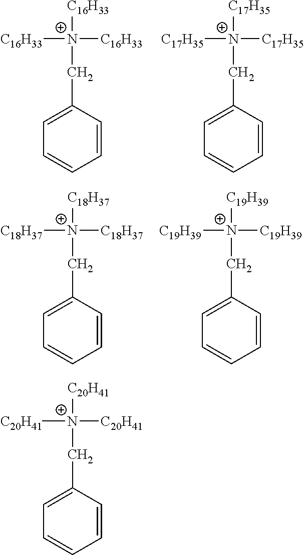

As to (A-3), the structure shown below is used,

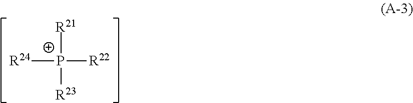

wherein R²¹ to R²⁴ represent the same meanings as the afore-mentioned (A-2).

Specific example thereof includes the following structures.

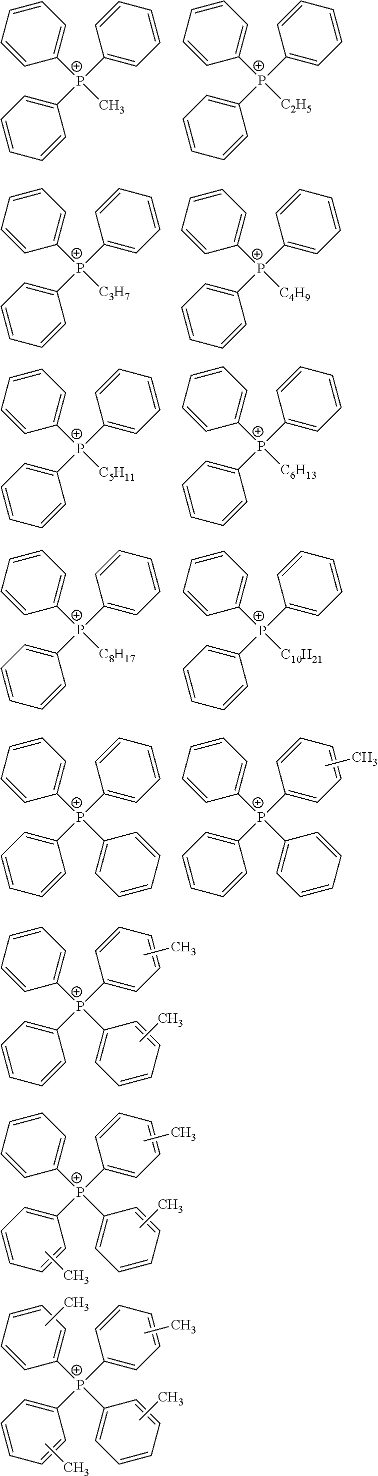

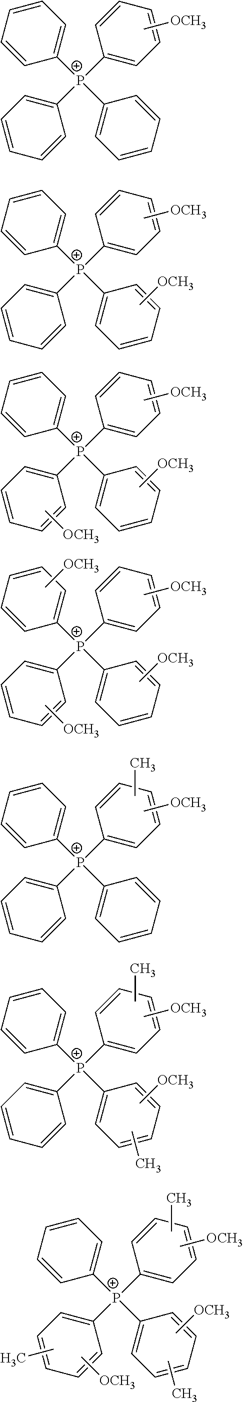

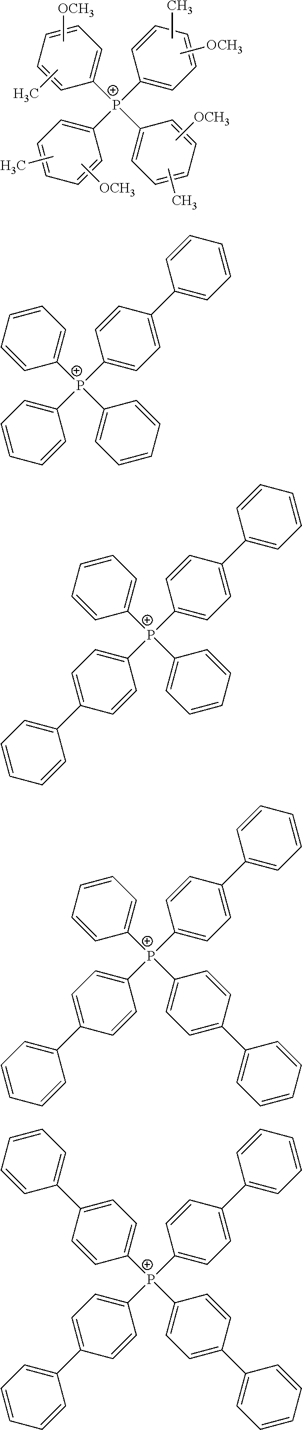

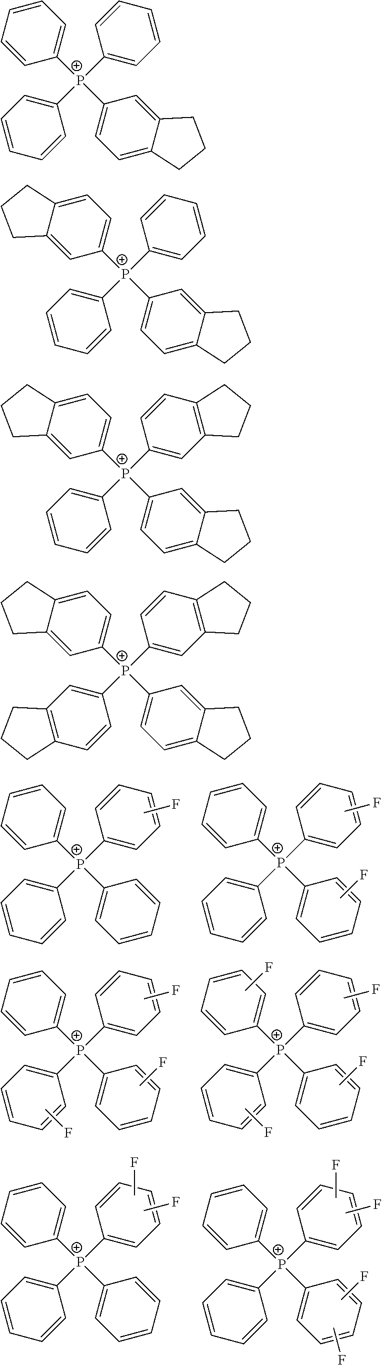

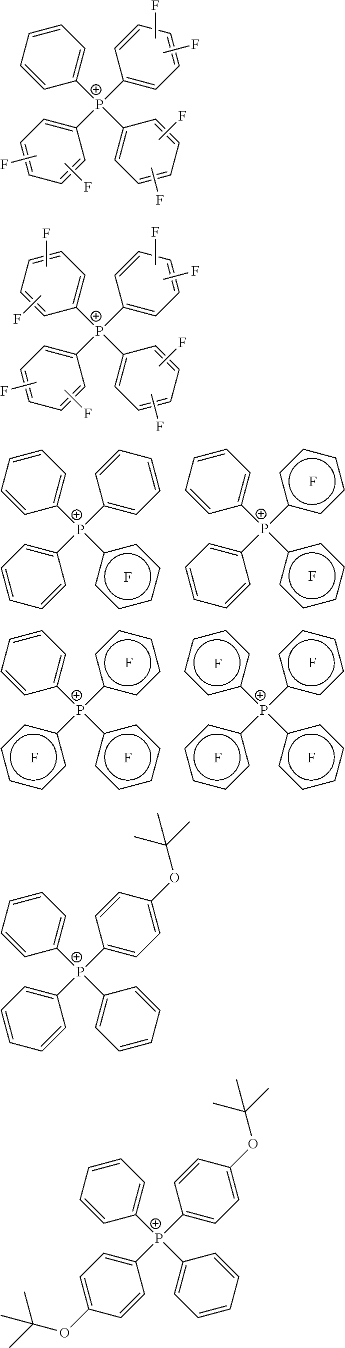

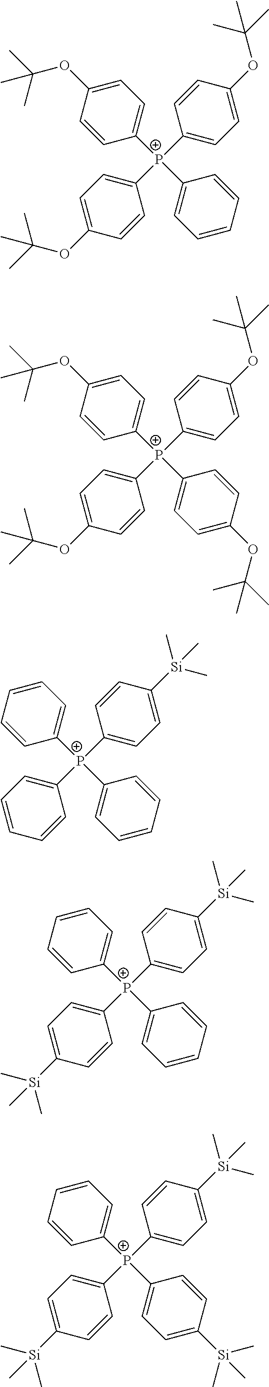

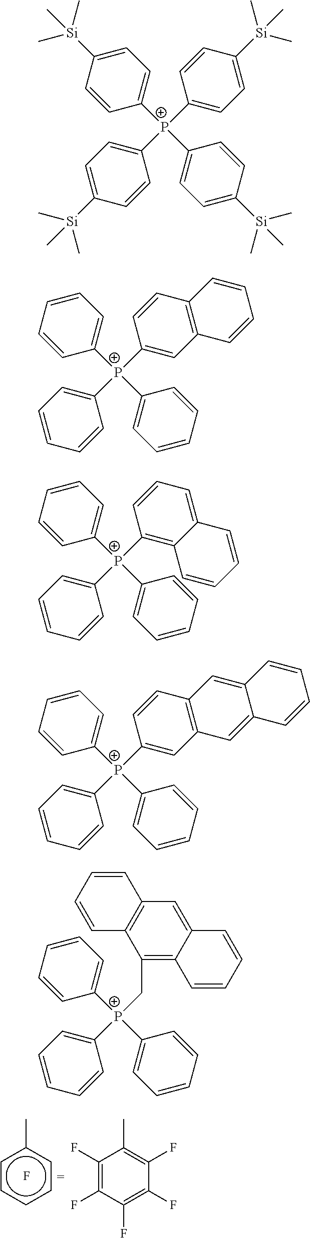

As to (A-4), the structure shown below is used,

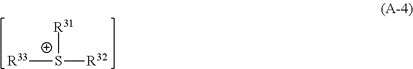

wherein R³¹ to R³³ represent the same meanings as R²¹ to R²⁴ that are described in the afore-mentioned (A-2), or may be a hydrogen atom. R³² and R³³ may form a ring, and in the case of forming a ring, R³² and R³³ each represents an alkylene group having 1 to 6 carbon atoms.

Specific example thereof includes the following structures.

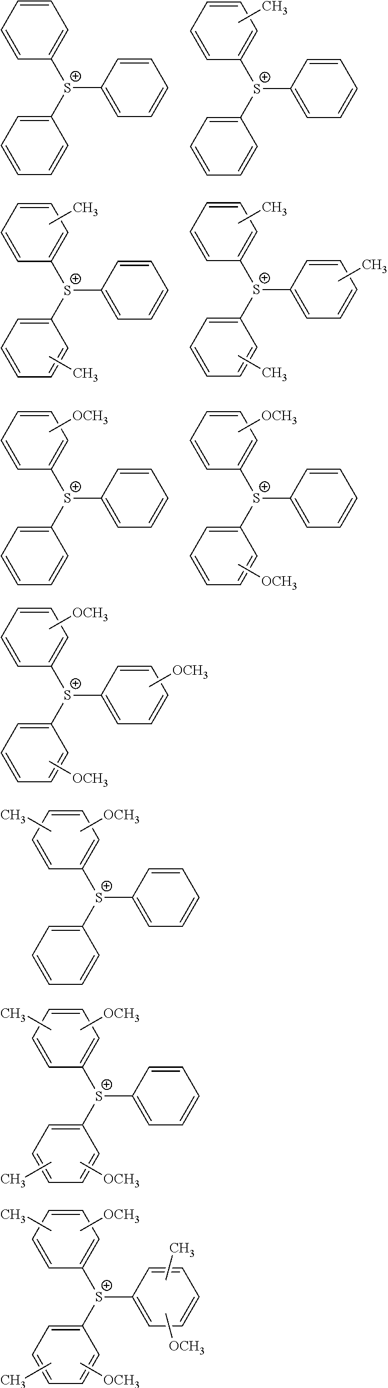

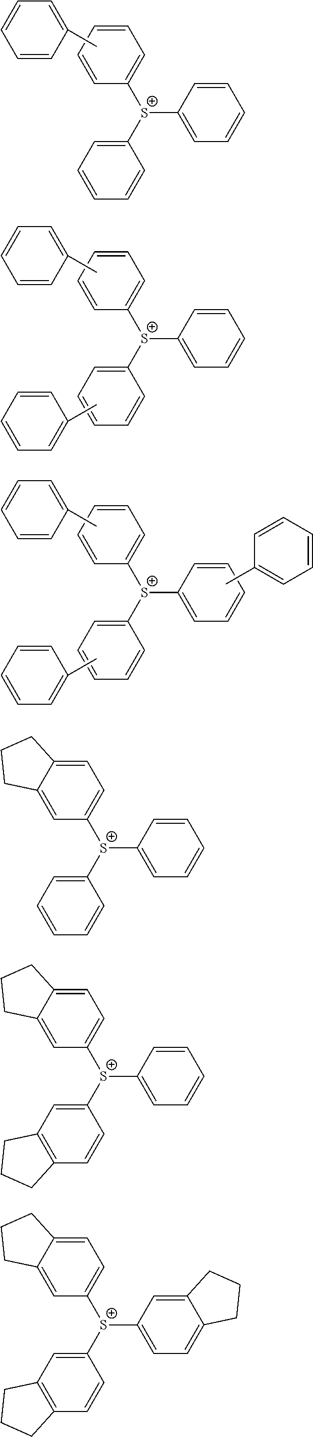

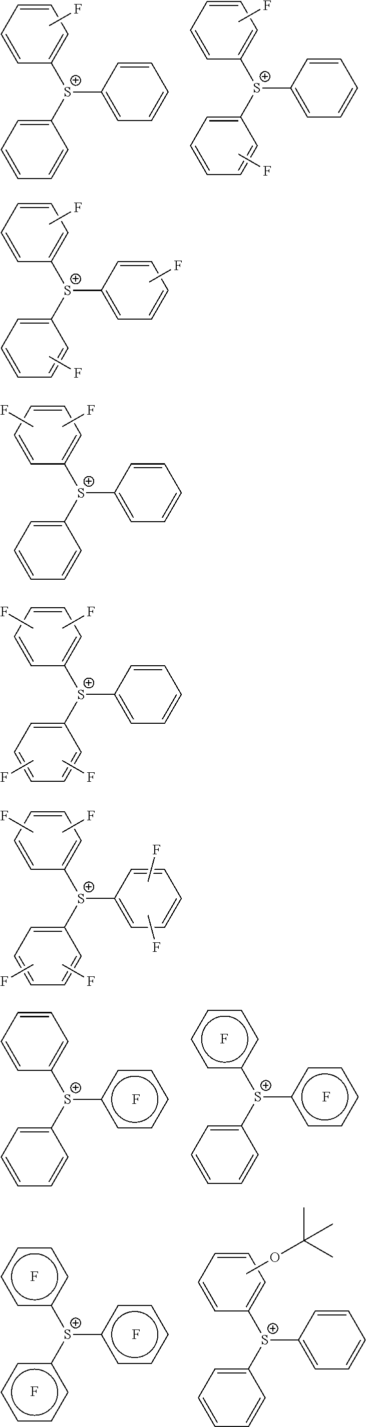

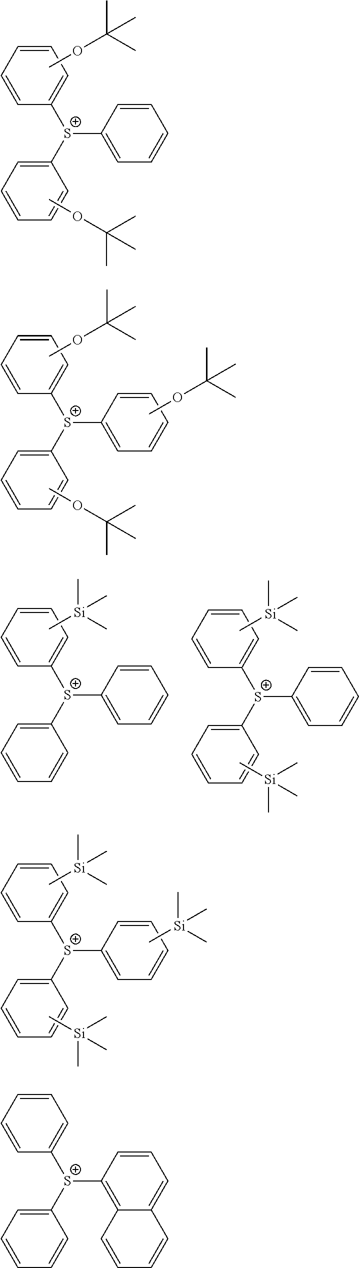

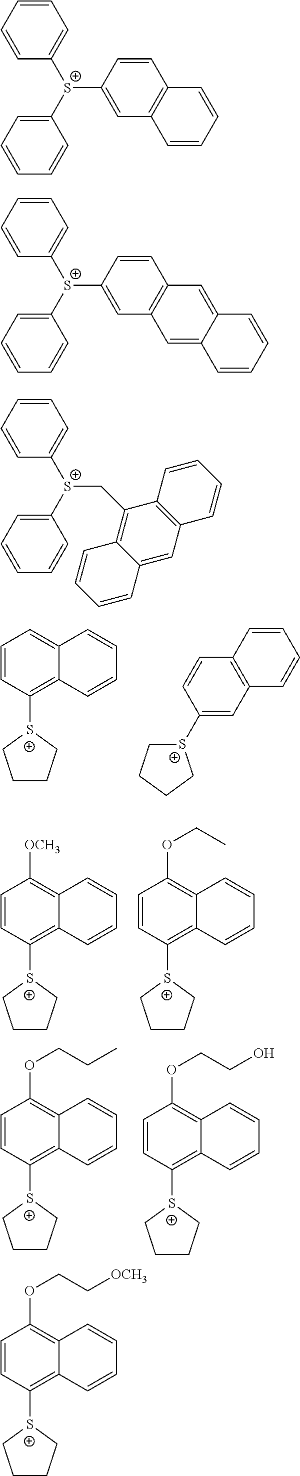

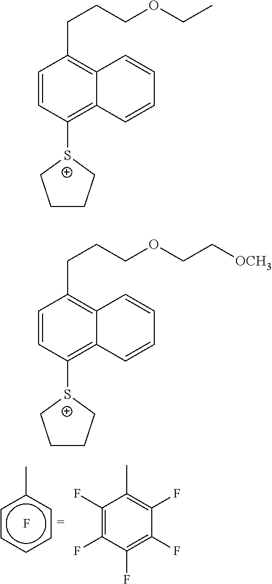

As to (A-5), the structure shown below is used,

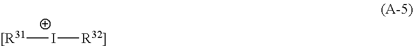

wherein R³¹ and R³³ represent the same meanings as R³¹ to R³² that are described in the afore-mentioned (A-4).

Specific example thereof includes the following structures.

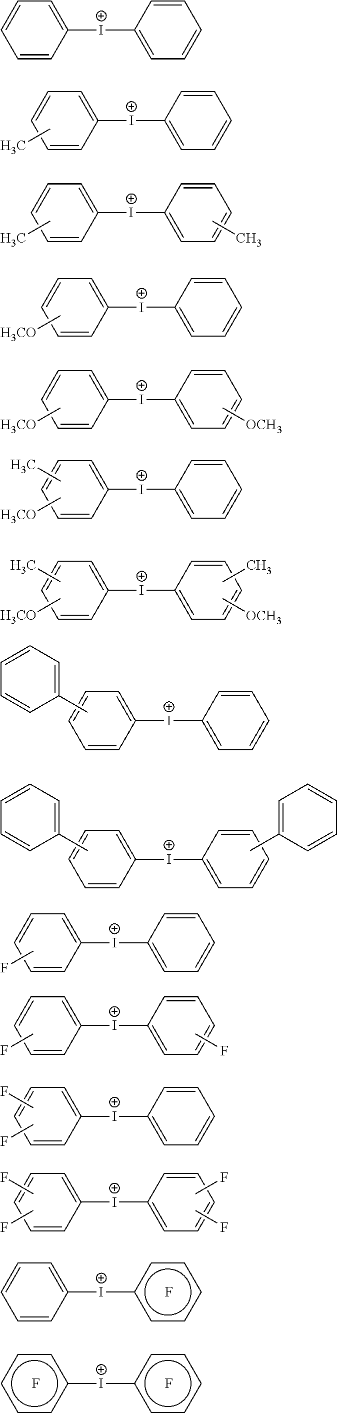

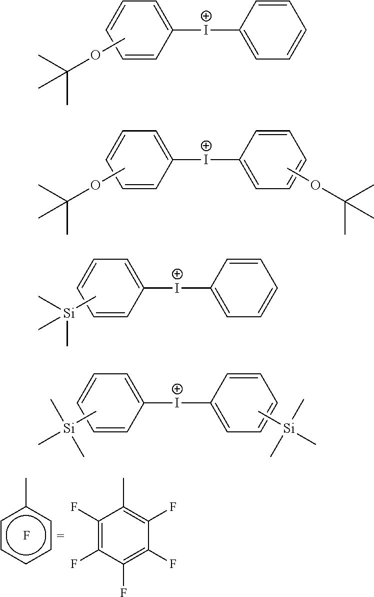

The thermal crosslinking accelerator of the present invention may be used one kind solely or as a combination of two or more kinds of them. Adding amount of the thermal crosslinking accelerator is preferably in the range of 0.01 to 50 parts by mass, or more preferably in the range of 0.1 to 40 parts by mass, relative to 100 parts by mass of a base polymer (polysiloxane obtained by the method to be mentioned later).

When the thermal crosslinking accelerator like this is used, for example, in a polysiloxane-containing resist underlayer film, excellent adhesion with the photoresist pattern formed thereon can be obtained while showing high etching selectivity to both the resist pattern formed thereon and the film formed thereunder such as, for example, an organic film; and thus, a pattern can be transferred in a good pattern form when the formed photoresist pattern is transferred sequentially to the polysiloxane-containing resist underlayer film and then to the organic underlayer film by using a dry etching process. Accordingly, finally the pattern formed in the upper layer resist can be transferred to a substrate with high precision.

The polysiloxane that is contained in the resist underlayer film forming composition of the present invention contains one or more compound selected from the group consisting of a compound shown by the following general formula (B-1), a hydrolysate thereof, a condensate thereof, and a hydrolysis-condensate thereof,

R^{1B}_{B1}R^{2B}_{B2}R^{3B}_{B3}Si(OR^{0B})_{(4-B1-B2-B3)} (B-1)

wherein R^{0B} represents a hydrocarbon group having 1 to 6 carbon atoms; and R^{1B}, R^{2B}, and R^{3B} represent a hydrogen atom or a monovalent organic group. B1, B2, and B3 represent 0 or 1, and 0≦B1+B2+B3≦3.

As to the hydrolysable silicon compound (B-1) used as a raw material (starting material) of the afore-mentioned polysiloxane, the following compounds may be mentioned as the examples thereof.

Illustrative example thereof includes trimethoxy silane, triethoxy silane, tripropoxy silane, triisopropoxy silane, methyl trimethoxy silane, methyl triethoxy silane, methyl tripropoxy silane, methyl triisopropoxy silane, ethyl trimethoxy silane, ethyl triethoxy silane, ethyl tripropoxy silane, ethyl triisopropoxy silane, vinyl trimethoxy silane, vinyl triethoxy silane, vinyl tripropoxy silane, vinyl triisopropoxy silane, propyl trimethoxy silane, propyl triethoxy silane, propyl tripropoxy silane, propyl triisopropoxy silane, isopropyl trimethoxy silane, isopropyl triethoxy silane, isopropyl tripropoxy silane, isopropyl triisopropoxy silane, butyl trimethoxy silane, butyl triethoxy silane, butyl tripropoxy silane, butyl triisopropoxy silane, sec-butyl trimethoxy silane, sec-butyl triethoxy silane, sec-butyl tripropoxy silane, sec-butyl triisopropoxy silane, t-butyl trimethoxy silane, t-butyl triethoxy silane, t-butyl tripropoxy silane, t-butyl triisopropoxy silane, cyclopropyl trimethoxy silane, cyclopropyl triethoxy silane, cyclopropyl tripropoxy silane, cyclopropyl triisopropoxy silane, cyclobutyl trimethoxy silane, cyclobutyl triethoxy silane, cyclobutyl tripropoxy silane, cyclobutyl triisopropoxy silane, cyclopentyl trimethoxy silane, cyclopentyl triethoxy silane, cyclopentyl tripropoxy silane, cyclopentyl triisopropoxy silane, cyclohexyl trimethoxy silane, cyclohexyl triethoxy silane, cyclohexyl tripropoxy silane, cyclohexyl triisopropoxy silane, cyclohexenyl trimethoxy silane, cyclohexenyl triethoxy silane, cyclohexenyl tripropoxy silane, cyclohexenyl triisopropoxy silane, cyclohexenylethyl trimethoxy silane, cyclohexenylethyl triethoxy silane, cyclohexenylethyl tripropoxy silane, cyclohexenylethyl triisopropoxy silane, cyclooctyl trimethoxy silane, cyclooctyl triethoxy silane, cyclooctyl tripropoxy silane, cyclooctyl triisopropoxy silane, cyclopentadienylpropyl trimethoxy silane, cyclopentadienylpropyl triethoxy silane, cyclopentadienylpropyl tripropoxy silane, cyclopentadienylpropyl triisopropoxy silane, bicycloheptenyl trimethoxy silane, bicycloheptenyl triethoxy silane, bicycloheptenyl tripropoxy silane, bicycloheptenyl triisopropoxy silane, bicycloheptyl trimethoxy silane, bicycloheptyl triethoxy silane, bicycloheptyl tripropoxy silane, bicycloheptyl triisopropoxy silane, adamantyl trimethoxy silane, adamantyl triethoxy silane, adamantyl tripropoxy silane, adamantyl triisopropoxy silane, phenyl trimethoxy silane, phenyl triethoxy silane, phenyl tripropoxy silane, phenyl triisopropoxy silane, benzyl trimethoxy silane, benzyl triethoxy silane, benzyl tripropoxy silane, benzyl triisopropoxy silane, tolyl trimethoxy silane, tolyl triethoxy silane, tolyl tripropoxy silane, tolyl triisopropoxy silane, anisyl trimethoxy silane, anisyl triethoxy silane, anisyl tripropoxy silane, anisyl triisopropoxy silane, phenethyl trimethoxy silane, phenethyl triethoxy silane, phenethyl tripropoxy silane, phenethyl triisopropoxy silane, naphthyl trimethoxy silane, naphthyl triethoxy silane, naphthyl tripropoxy silane, naphthyl triisopropoxy silane, dimethyl dimethoxy silane, dimethyl diethoxy silane, methyl ethyl dimethoxy silane, methyl ethyl diethoxy silane, dimethyl dipropoxy silane, dimethyl diisopropoxy silane, diethyl dimethoxy silane, diethyl diethoxy silane, diethyl dipropoxy silane, diethyl diisopropoxy silane, dipropyl dimethoxy silane, dipropyl diethoxy silane, dipropyl dipropoxy silane, dipropyl diisopropoxy silane, diisopropyl dimethoxy silane, diisopropyl diethoxy silane, diisopropyl dipropoxy silane, diisopropyl diisopropoxy silane, dibutyl dimethoxy silane, dibutyl diethoxy silane, dibutyl dipropoxy silane, dibutyl diisopropoxy silane, di-sec-butyl dimethoxy silane, di-sec-butyl diethoxy silane, di-sec-butyl dipropoxy silane, di-sec-butyl diisopropoxy silane, di-t-butyl dimethoxy silane, di-t-butyl diethoxy silane, di-t-butyl dipropoxy silane, di-t-butyl diisopropoxy silane, dicyclopropyl dimethoxy silane, dicyclopropyl diethoxy silane, dicyclopropyl dipropoxy silane, dicyclopropyl diisopropoxy silane, dicyclobutyl dimethoxy silane, dicyclobutyl diethoxy silane, dicyclobutyl dipropoxy silane, dicyclobutyl diisopropoxy silane, dicyclopentyl dimethoxy silane, dicyclopentyl diethoxy silane, dicyclopentyl dipropoxy silane, dicyclopentyl diisopropoxy silane, dicyclohexyl dimethoxy silane, dicyclohexyl diethoxy silane, dicyclohexyl dipropoxy silane, dicyclohexyl diisopropoxy silane, dicyclohexenyl dimethoxy silane, dicyclohexenyl diethoxy silane, dicyclohexenyl dipropoxy silane, dicyclohexenyl diisopropoxy silane, dicyclohexenylethyl dimethoxy silane, dicyclohexenylethyl diethoxy silane, dicyclohexenylethyl dipropoxy silane, dicyclohexenylethyl diisopropoxy silane, dicyclooctyl dimethoxy silane, dicyclooctyl diethoxy silane, dicyclooctyl dipropoxy silane, dicyclooctyl diisopropoxy silane, dicyclopentadienylpropyl dimethoxy silane, dicyclopentadienylpropyl diethoxy silane, dicyclopentadienylpropyl dipropoxy silane, dicyclopentadienylpropyl diisopropoxy silane, bis(bicycloheptenyl) dimethoxy silane, bis(bicycloheptenyl) diethoxy silane, bis(bicycloheptenyl) dipropoxy silane, bis(bicycloheptenyl) diisopropoxy silane, bis(bicycloheptyl) dimethoxy silane, bis(bicycloheptyl) diethoxy silane, bis(bicycloheptyl) dipropoxy silane, bis(bicycloheptyl) diisopropoxy silane, diadamantyl dimethoxy silane, diadamantyl diethoxy silane, diadamantyl dipropoxy silane, diadamantyl diisopropoxy silane, diphenyl dimethoxy silane, diphenyl diethoxy silane, methyl phenyl dimethoxy silane, methyl phenyl diethoxy silane, diphenyl dipropoxy silane, diphenyl diisopropoxy silane, trimethyl methoxy silane, trimethyl ethoxy silane, dimethyl ethyl methoxy silane, dimethyl ethyl ethoxy silane, dimethyl phenyl methoxy silane, dimethyl phenyl ethoxy silane, dimethyl benzyl methoxy silane, dimethyl benzyl ethoxy silane, dimethyl phenethyl methoxy silane, and dimethyl phenethyl ethoxy silane.

In addition, the compound shown by the general formula (B-1) may contain, on the silicon atoms shown by the following structures, 2 or 3 of a methoxy group, an ethoxy group, a propoxy group, a butoxy group, a pentoxy group, a cyclopentoxy group, a hexyloxy group, a cyclohexyloxy group, and a phenoxy group, as a hydrolysable group represented by OR^{0B}.

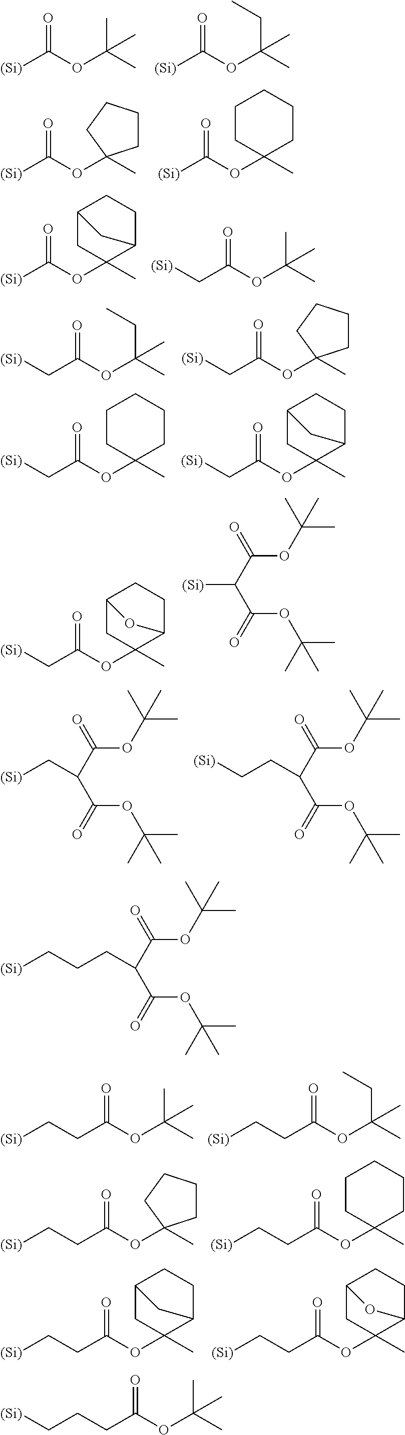

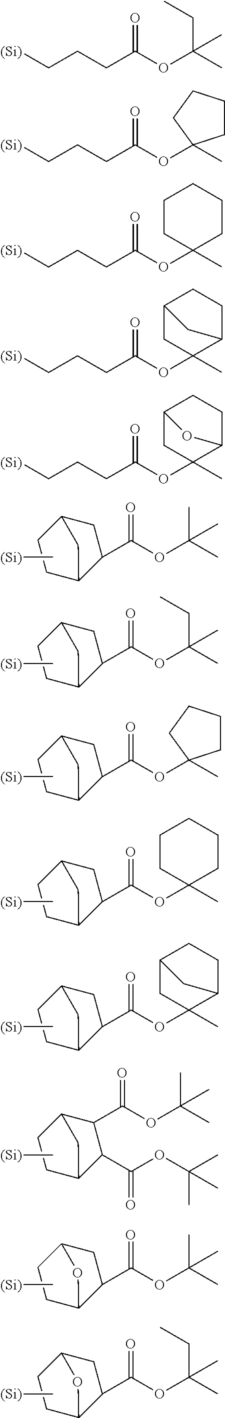

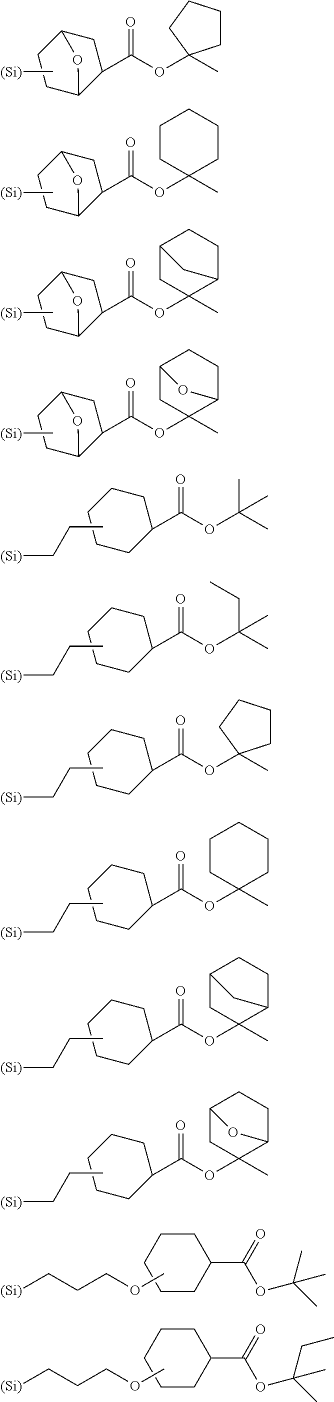

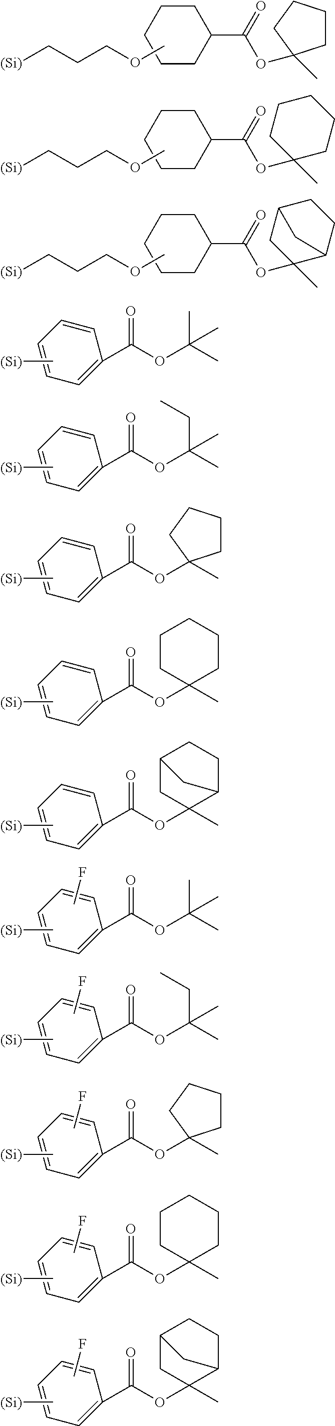

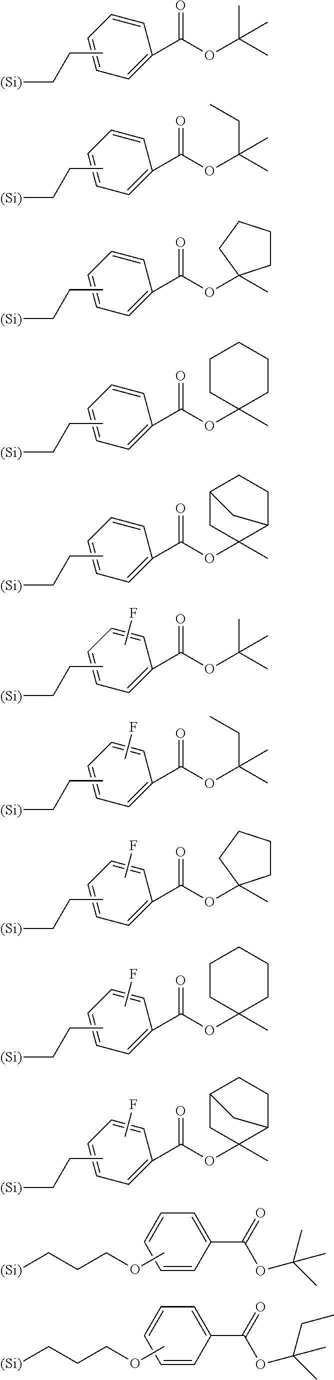

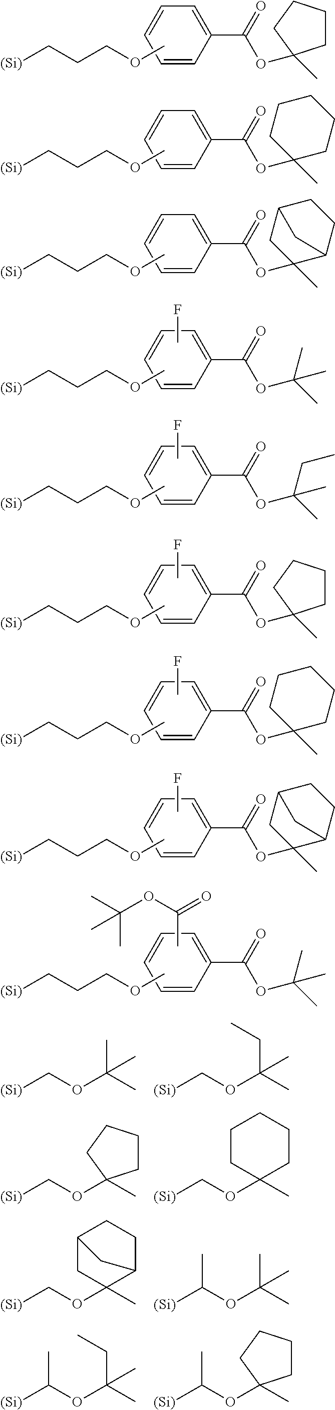

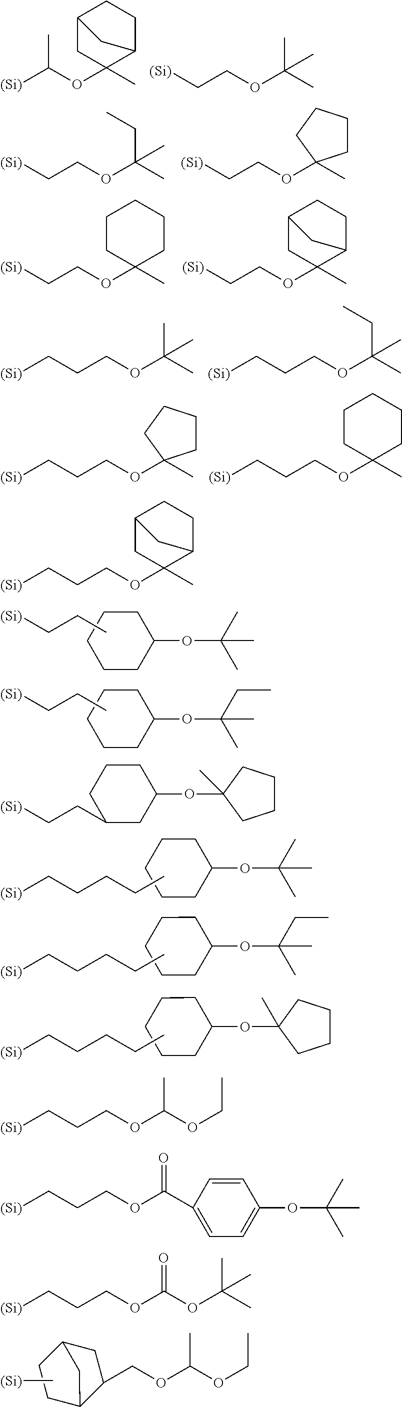

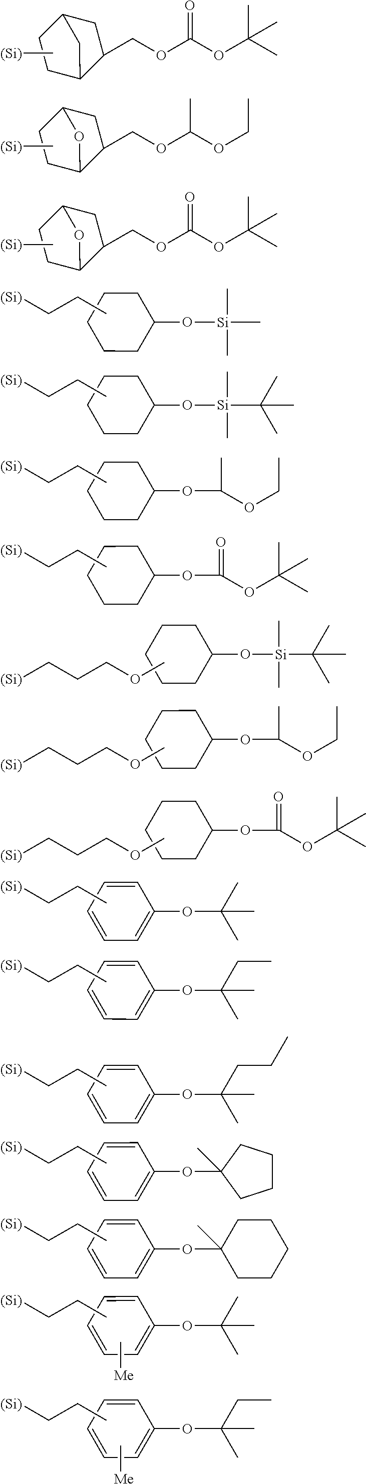

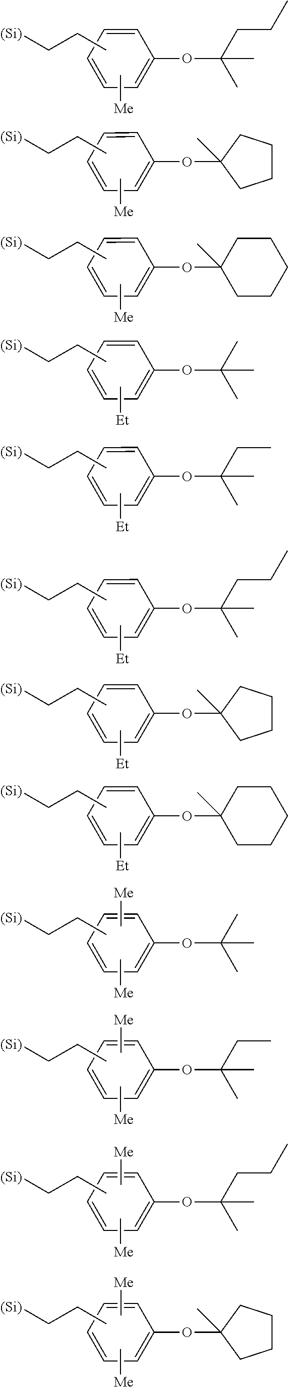

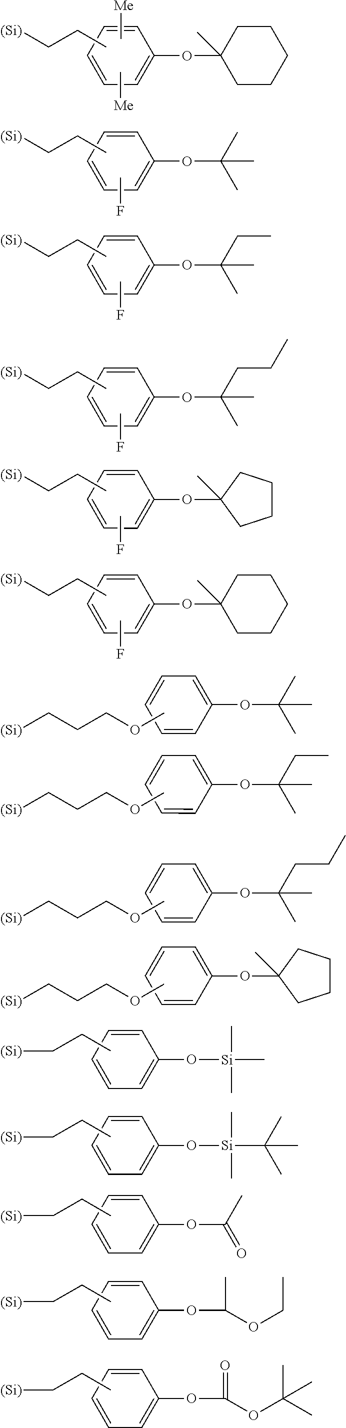

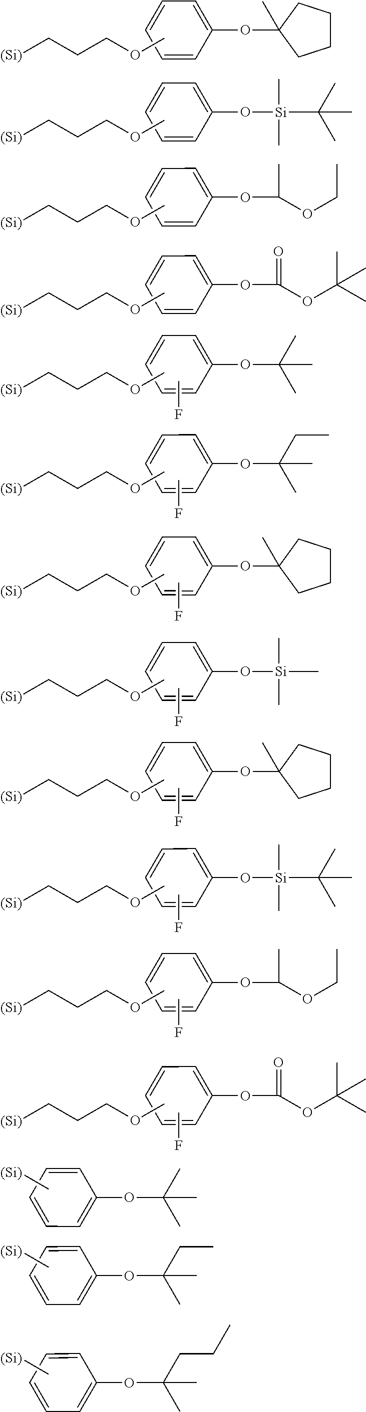

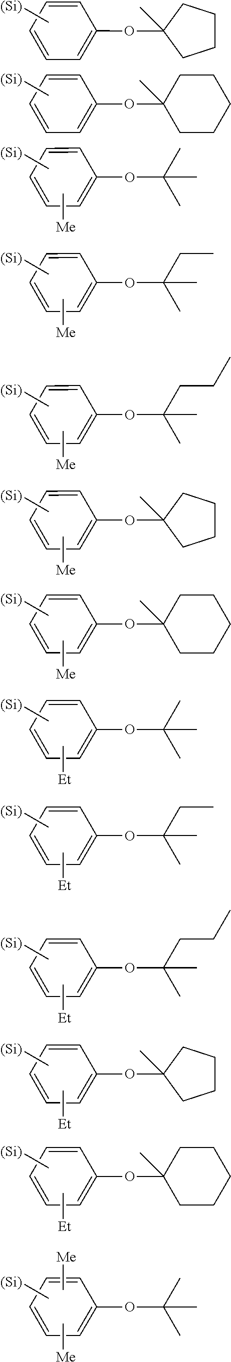

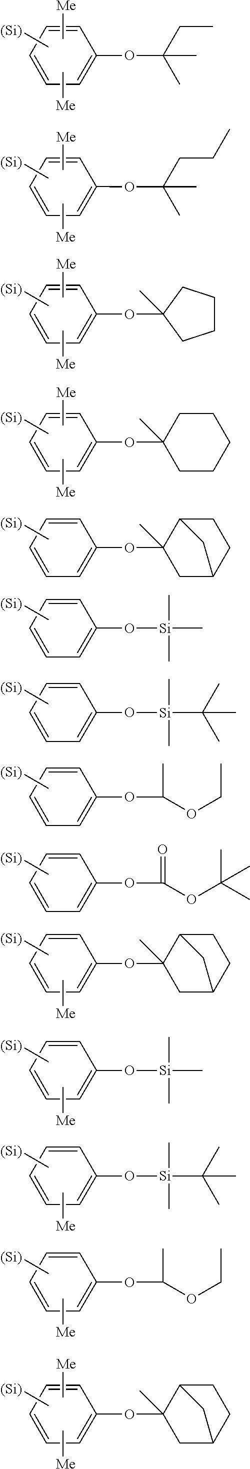

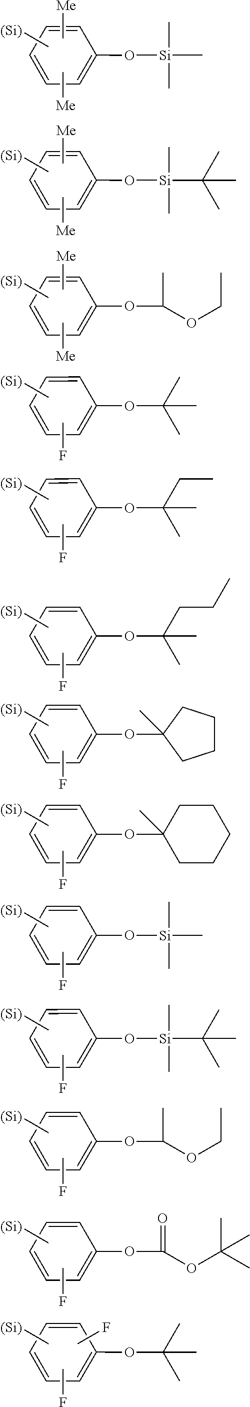

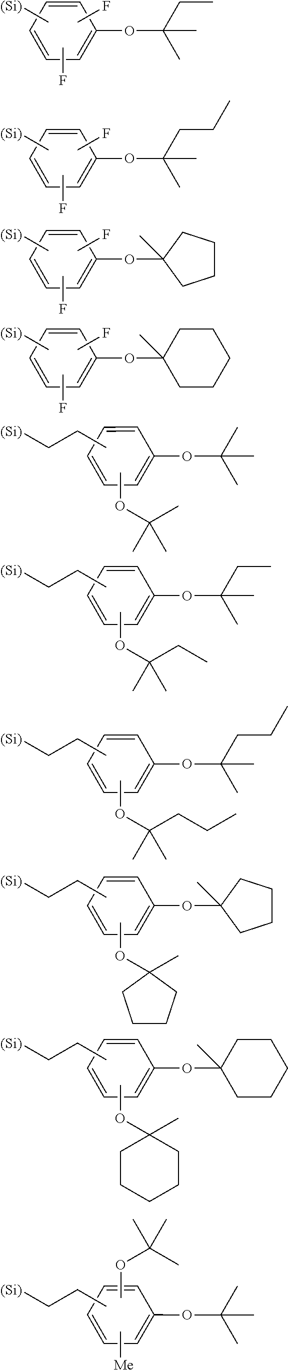

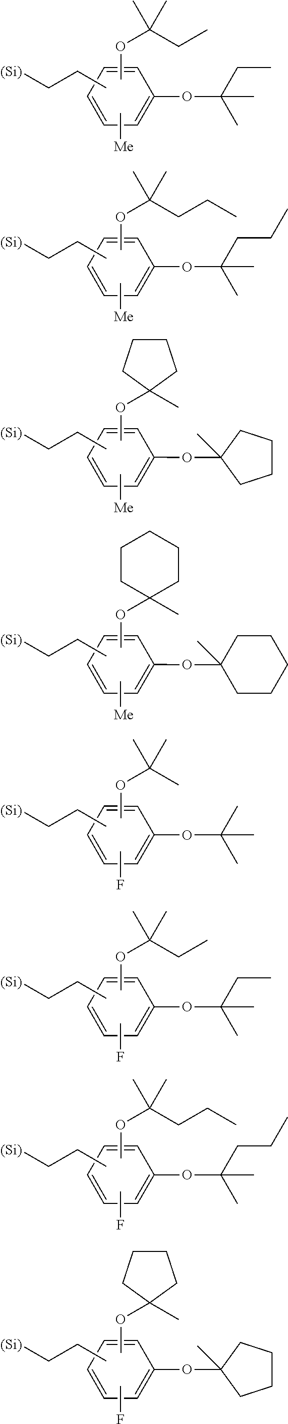

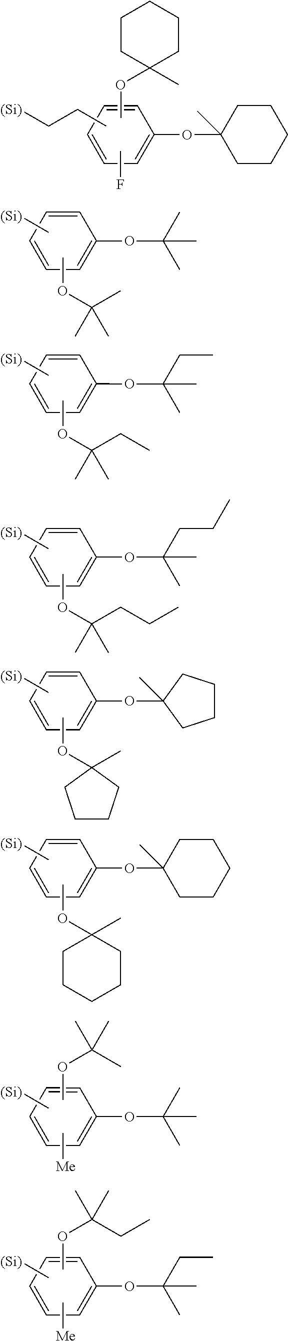

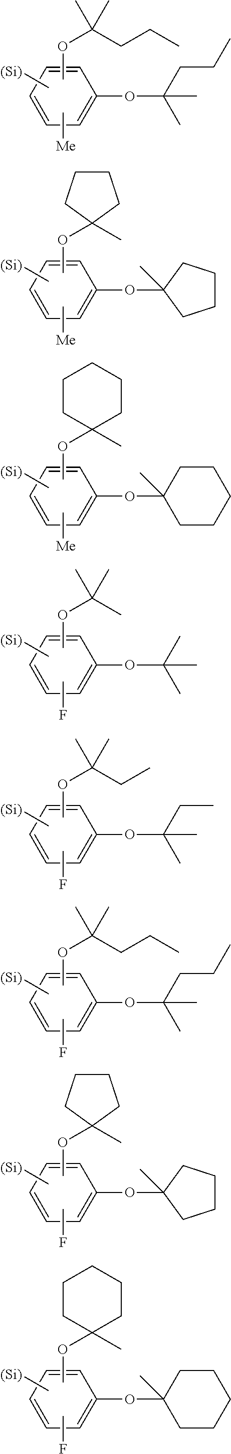

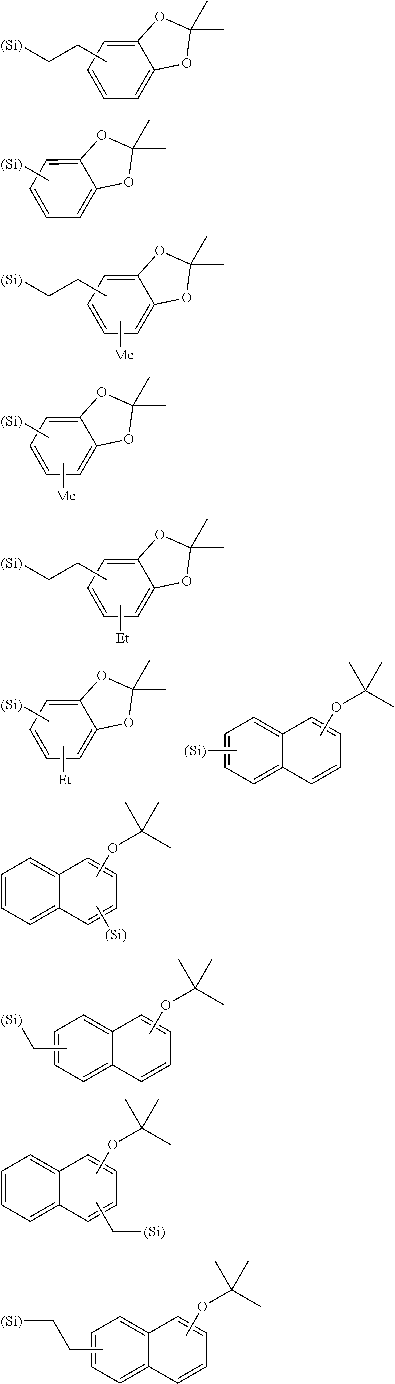

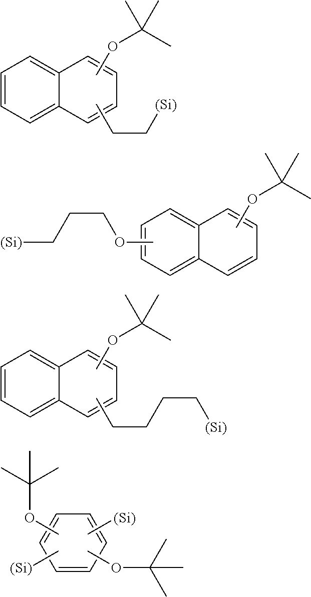

As to the raw material of the polysiloxane used in the present invention, a hydrolysable metal compound (B-2) may be mentioned as the example thereof other than the afore-mentioned general formula (B-1),

L′(OR^{4B})_{B4}(OR^{5B})_{B5}(O)_{B6} (B-2)

wherein R^{4B} and R^{5B} represent an organic group having 1 to 30 carbon atoms; B4+B5+B6 is a valency that is determined by the kind of L′; B4, B5, and B6 represent an integer of 0 or more; and L′ represents an element belonging to the III group, the IV group, or the V group of the periodic table except for carbon.

As to (B-2), followings may be mentioned as the examples thereof. When L′ is boron, illustrative example of the compound shown by the general formula (B-2) as the monomer includes boron methoxide, boron ethoxide, boron propoxide, boron butoxide, boron amyloxide, boron hexyloxide, boron cyclopentoxide, boron cyclohexyloxide, boron allyloxide, boron phenoxide, boron methoxyethoxide, boric acid, and boron oxide.

When L′ is aluminum, illustrative example of the compound shown by the general formula (B-2) as the monomer includes aluminum methoxide, aluminum ethoxide, aluminum propoxide, aluminum butoxide, aluminum amyloxide, aluminum hexyloxide, aluminum cyclopentoxide, aluminum cyclohexyloxide, aluminum allyloxide, aluminum phenoxide, aluminum methoxyethoxide, aluminum ethoxyethoxide, aluminum dipropoxyethyl acetoacetate, aluminum dibutoxyethyl acetoacetate, aluminum propoxy bisethylacetoacetate, aluminum butoxy bisethylacetoacetate, aluminum 2,4-pentanedionate, and aluminum 2,2,6,6-tetramethyl-3,5-heptanedionate.

When L′ is gallium, illustrative example of the compound shown by the general formula (B-2) as the monomer includes gallium methoxide, gallium ethoxide, gallium propoxide, gallium butoxide, gallium amyloxide, gallium hexyloxide, gallium cyclopentoxide, gallium cyclohexyloxide, gallium allyloxide, gallium phenoxide, gallium methoxyethoxide, gallium ethoxyethoxide, gallium dipropoxyethyl acetoacetate, gallium dibutoxyethyl acetoacetate, gallium propoxy bisethylacetoacetate, gallium butoxy bisethylacetoacetate, gallium 2,4-pentanedionate, and gallium 2,2,6,6-tetramethyl-3,5-heptanedionate.

When L′ is yttrium, illustrative example of the compound shown by the general formula (B-2) as the monomer includes yttrium methoxide, yttrium ethoxide, yttrium propoxide, yttrium butoxide, yttrium amyloxide, yttrium hexyloxide, yttrium cyclopentoxide, yttrium cyclohexyloxide, yttrium allyloxide, yttrium phenoxide, yttrium methoxyethoxide, yttrium ethoxyethoxide, yttrium dipropoxyethyl acetoacetate, yttrium dibutoxyethyl acetoacetate, yttrium propoxy bisethylacetoacetate, yttrium butoxy bisethylacetoacetate, yttrium 2,4-pentanedionate, and yttrium 2,2,6,6-tetramethyl-3,5-heptanedionate.

When L′ is germanium, illustrative example of the compound shown by the general formula (B-2) as the monomer includes germanium methoxide, germanium ethoxide, germanium propoxide, germanium butoxide, germanium amyloxide, germanium hexyloxide, germanium cyclopentoxide, germanium cyclohexyloxide, germanium allyloxide, germanium phenoxide, germanium methoxyethoxide, and germanium ethoxyethoxide.

When L′ is titanium, illustrative example of the compound shown by the general formula (B-2) as the monomer includes titanium methoxide, titanium ethoxide, titanium propoxide, titanium butoxide, titanium amyloxide, titanium hexyloxide, titanium cyclopentoxide, titanium cyclohexyloxide, titanium allyloxide, titanium phenoxide, titanium methoxyethoxide, titanium ethoxyethoxide, titanium dipropoxy bisethylacetoacetate, titanium dibutoxy bisethylacetoacetate, titanium dipropoxy bis-2,4-pentanedionate, and titanium dibutoxy bis-2,4-pentanedionate.

When L′ is hafnium, illustrative example of the compound shown by the general formula (B-2) as the monomer includes hafnium methoxide, hafnium ethoxide, hafnium propoxide, hafnium butoxide, hafnium amyloxide, hafnium hexyloxide, hafnium cyclopentoxide, hafnium cyclohexyloxide, hafnium allyloxide, hafnium phenoxide, hafnium methoxyethoxide, hafnium ethoxyethoxide, hafnium dipropoxy bisethylacetoacetate, hafnium dibutoxy bisethylacetoacetate, hafnium dipropoxy bis-2,4-pentanedionate, and hafnium dibutoxy bis-2,4-pentanedionate.

When L′ is tin, illustrative example of the compound shown by the general formula (B-2) as the monomer includes methoxy tin, ethoxy tin, propoxy tin, butoxy tin, phenoxy tin, methoxyethoxy tin, ethoxyethoxy tin, tin 2,4-pentanedionate, and tin 2,2,6,6-tetramethyl-3,5-heptanedionate.

When L′ is arsenic, illustrative example of the compound shown by the general formula (B-2) as the monomer includes methoxy arsenic, ethoxy arsenic, propoxy arsenic, butoxy arsenic, and phenoxy arsenic.

When L′ is antimony, illustrative example of the compound shown by the general formula (B-2) as the monomer includes methoxy antimony, ethoxy antimony, propoxy antimony, butoxy antimony, phenoxy antimony, antimony acetate, and antimony propionate.

When L′ is niobium, illustrative example of the compound shown by the general formula (B-2) as the monomer includes methoxy niobium, ethoxy niobium, propoxy niobium, butoxy niobium, and phenoxy niobium.

When L′ is tantalum, illustrative example of the compound shown by the general formula (B-2) as the monomer includes methoxy tantalum, ethoxy tantalum, propoxy tantalum, butoxy tantalum, and phenoxy tantalum.

When L′ is bismuth, illustrative example of the compound shown by the general formula (B-2) as the monomer includes methoxy bismuth, ethoxy bismuth, propoxy bismuth, butoxy bismuth, and phenoxy bismuth.

When L′ is phosphorous, illustrative example of the compound shown by the general formula (B-2) as the monomer includes trimethyl phosphite, triethyl phosphite, tripropyl phosphite, trimethyl phosphate, triethyl phosphate, tripropyl phosphate, and diphosphorous pentaoxide.

When L′ is vanadium, illustrative example of the compound shown by the general formula (B-2) as the monomer includes vanadium oxide bis(2,4-pentanedionate), vanadium 2,4-pentanedionate, vanadium tributoxide oxide, and vanadium tripropoxide oxide.

When L′ is zirconium, illustrative example of the compound shown by the general formula (B-2) as the monomer includes methoxy zirconium, ethoxy zirconium, propoxy zirconium, butoxy zirconium, phenoxy zirconium, zirconium dibutoxide bis(2,4-pentanedionate), and zirconium dipropoxide bis(2,2,6,6-tetramethyl-3,5-heptanedionate).

When L′ is tantalum, illustrative example of the compound shown by the general formula (B-2) as the monomer includes methoxy tantalum, ethoxy tantalum, propoxy tantalum, butoxy tantalum, and phenoxy tantalum.

One or more monomers as shown above may be chosen for a raw material which mixed before or during the reaction for forming the polysiloxane.

The polysiloxane used in the present invention may be produced by carrying out the hydrolysis-condensation reaction of a compound shown by the general formula (B-1) and, if necessary, a compound shown by the general formula (B-2) by using one or more compound selected from the group consisting of an inorganic acid, an aliphatic sulfonic acid, and an aromatic sulfonic acid, as an acid catalyst.

Illustrative example of the usable acid catalyst for this reaction includes hydrofluoric acid, hydrochloric acid, hydrobromic acid, sulfuric acid, nitric acid, perchloric acid, phosphoric acid, methanesulfonic acid, benzenesulfonic acid, and toluenesulfonic acid. Use amount of the catalyst is in the range of 10⁻⁶ to 10 moles, preferably in the range of 10⁻⁵ to 5 moles, or more preferably in the range of 10⁻⁴ to 1 mole, relative to 1 mole of the monomer.

Amount of water to obtain the polysiloxane by the hydrolysis-condensation reaction of these monomers is preferably in the range of 0.01 to 100 moles, more preferably in the range of 0.05 to 50 moles, or still more preferably in the range of 0.1 to 30 moles, relative to 1 mole of the hydrolysable substituent group which is bonded to the monomer. The adding amount of 100 moles or more only leads to an excessively large equipment for the reaction, so that it is uneconomical.

In the operation for this, the hydrolysis-condensation reaction starts by adding a monomer to an aqueous catalyst solution. At this time, an organic solvent may be added into the aqueous catalyst solution, or the monomer may be diluted by an organic solvent, or both of them may be conducted. The reaction temperature is in the range of 0 to 100° C., or preferably in the range of 5 to 80° C. It is preferable that the temperature be kept in the range of 5 to 80° C. during the time of dropwise addition of the monomer, and thereafter, ageing be conducted in the temperature range of 20 to 80° C.

Illustrative example of the preferable organic solvent which can be added to the aqueous catalyst solution or can dilute the monomer includes methanol, ethanol, 1-propanol, 2-propanol, 1-butanol, 2-butanol, 2-methyl-1-propanol, acetone, acetonitrile, tetrahydrofuran, toluene, hexane, ethyl acetate, cyclohexanone, methyl amyl ketone, butanediol monomethyl ether, propylene glycol monomethyl ether, ethylene glycol monomethyl ether, butanediol monoethyl ether, propylene glycol monoethyl ether, ethylene glycol monoethyl ether, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, t-butyl acetate, t-butyl propionate, propylene glycol mono-t-butyl ether acetate, γ-butyrolactone, and a mixture of these solvents.

Among these organic solvents, a water-soluble solvent is preferable. Illustrative example thereof includes an alcohol such as methanol, ethanol, 1-propanol, and 2-propanol; a polyol such as ethylene glycol and propylene glycol; a polyol condensation derivative such as butanediol monomethyl ether, propylene glycol monomethyl ether, ethylene glycol monomethyl ether, butanediol monoethyl ether, propylene glycol monoethyl ether, ethylene glycol monoethyl ether, butanediol monopropyl ether, propylene glycol monopropyl ether, and ethylene glycol monopropyl ether; acetone, acetonitrile, and tetrahydrofuran. Among them, a solvent having a boiling point of 100° C. or lower is particularly preferable.

Meanwhile, use amount of the organic solvent is preferably in the range of 0 to 1000 mL, or especially preferably in the range of 0 to 500 mL, relative to 1 mole of the monomer. Using too much of the organic solvent leads to an excessively large reactor, so that this is uneconomical.

Thereafter, if necessary, a neutralization reaction of the catalyst is carried out, and then, an alcohol formed during the hydrolysis-condensation reaction is removed under reduced pressure to obtain an aqueous reaction mixture solution. Use amount of a basic substance for neutralization is preferably in the range of 0.1 to 2 equivalents relative to the acid used as the catalyst. Any basic substance may be used that shows a basic property in water.

Then, it is preferable to remove from the reaction mixture a byproduct such as an alcohol produced by the hydrolysis-condensation reaction. Temperature to heat the reaction mixture in this operation is preferably in the range of 0 to 100° C., more preferably in the range of 10 to 90° C., or still more preferably in the range of 15 to 80° C., though it depends on the kinds of an added organic solvent, and an alcohol and the like produced by the reaction. Degree of the vacuum in this operation is preferably an atmospheric pressure or lower, more preferably 80 kPa or lower in the absolute pressure, or still more preferably 50 kPa or lower in the absolute pressure, though it depends on the kinds of an organic solvent, an alcohol, and so forth to be removed, of an exhausting equipment, and of a condensation equipment, as well as heating temperature. Although it is difficult to know exactly an amount of the alcohol removed, it is preferable that about 80% or more by mass of a produced alcohol and so forth be removed.

Then, the acid catalyst used in the hydrolysis-condensation reaction may be removed from the reaction mixture. The acid catalyst may be removed by mixing the polysiloxane with water, and then, extracting the polysiloxane by an organic solvent. The organic solvent which can dissolve the polysiloxane while can be separated into two layers when mixed with water is preferably used. Illustrative example of the organic solvent includes methanol, ethanol, 1-propanol, 2-propanol, 1-butanol, 2-butanol, 2-methyl-1-propanol, acetone, tetrahydrofuran, toluene, hexane, ethyl acetate, cyclohexanone, methyl amyl ketone, butanediol monomethyl ether, propylene glycol monomethyl ether, ethylene glycol monomethyl ether, butanediol monoethyl ether, propylene glycol monoethyl ether, ethylene glycol monoethyl ether, butanediol monopropyl ether, propylene glycol monopropyl ether, ethylene glycol monopropyl ether, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, t-butyl acetate, t-butyl propionate, propylene glycol mono-t-butyl ether acetate, γ-butyrolactone, methyl isobutyl ketone, cyclopentyl methyl ether, and a mixture of them.

In addition, a mixture of a water-soluble organic solvent and a water-insoluble organic solvent may also be used. Illustrative examples of the preferable combination thereof include methanol and ethyl acetate, ethanol and ethyl acetate, 1-propanol and ethyl acetate, 2-propanol and ethyl acetate, butanediol monomethyl ether and ethyl acetate, propylene glycol monomethyl ether and ethyl acetate, ethylene glycol monomethyl ether and ethyl acetate, butanediol monoethyl ether and ethyl acetate, propylene glycol monoethyl ether and ethyl acetate, ethylene glycol monoethyl ether and ethyl acetate, butanediol monopropyl ether and ethyl acetate, propylene glycol monopropyl ether and ethyl acetate, ethylene glycol monopropyl ether and ethyl acetate, methanol and methyl isobutyl ketone, ethanol and methyl isobutyl ketone, 1-propanol and methyl isobutyl ketone, 2-propanol and methyl isobutyl ketone, propylene glycol monomethyl ether and methyl isobutyl ketone, ethylene glycol monomethyl ether and methyl isobutyl ketone, propylene glycol monoethyl ether and methyl isobutyl ketone, ethylene glycol monoethyl ether and methyl isobutyl ketone, propylene glycol monopropyl ether and methyl isobutyl ketone, ethylene glycol monopropyl ether and methyl isobutyl ketone, methanol and cyclopentyl methyl ether, ethanol and cyclopentyl methyl ether, 1-propanol and cyclopentyl methyl ether, 2-propanol and cyclopentyl methyl ether, propylene glycol monomethyl ether and cyclopentyl methyl ether, ethylene glycol monomethyl ether and cyclopentyl methyl ether, propylene glycol monoethyl ether and cyclopentyl methyl ether, ethylene glycol monoethyl ether and cyclopentyl methyl ether, propylene glycol monopropyl ether and cyclopentyl methyl ether, ethylene glycol monopropyl ether and cyclopentyl methyl ether, methanol and propylene glycol methyl ether acetate, ethanol and propylene glycol methyl ether acetate, 1-propanol and propylene glycol methyl ether acetate, 2-propanol and propylene glycol methyl ether acetate, propylene glycol monomethyl ether and propylene glycol methyl ether acetate, ethylene glycol monomethyl ether and propylene glycol methyl ether acetate, propylene glycol monoethyl ether and propylene glycol methyl ether acetate, ethylene glycol monoethyl ether and propylene glycol methyl ether acetate, propylene glycol monopropyl ether and propylene glycol methyl ether acetate, and ethylene glycol monopropyl ether and propylene glycol methyl ether acetate, though the combination is not limited to the above.

Meanwhile, mixing ratio of the water-soluble organic solvent to the water-insoluble organic solvent is arbitrarily selected, while the amount of the water-soluble organic solvent is in the range of 0.1 to 1000 parts by mass, preferably in the range of 1 to 500 parts by mass, or more preferably in the range of 2 to 100 parts by mass, relative to 100 parts by mass of the water-insoluble organic solvent.

Then, washing by neutral water may be done. As to the water, so-called de-ionized water or ultrapure water may be used. Amount of this water is in the range of 0.01 to 100 liters, preferably in the range of 0.05 to 50 liters, or more preferably in the range of 0.1 to 5 liters, relative to 1 liter of the polysiloxane solution. This washing operation may be done in such a way that the both solutions are mixed in a vessel by agitation, and then settled to separate a water layer. Number of washing may be 1 time or more, though the range of about 1 to about 5 times is preferable, because washing of 10 times or more is not worth to have full effects thereof.

Alternatively, the acid catalyst may be removed by a method using an ion-exchange resin, or a method that the acid catalyst is neutralized by an epoxy compound such as ethylene oxide and propylene oxide, and then removed. These methods may be selected arbitrarily according to the acid catalyst used in the reaction.

In this operation of water-washing, number of washing and amount of water for washing may be determined arbitrarily in view of effects of catalyst removal and fractionation because there is a case that a part of the polysiloxane escapes into a water layer, thereby substantially the same effect as fractionation operation is obtained.

To any of the polysiloxane solution which the acid catalyst remained therein and which the acid catalyst removed therefrom is added a final solvent, and then, the solvents therein are exchanged under reduced pressure to obtain a polysiloxane solution. Temperature at the time of this solvent exchange operation is preferably in the range of 0 to 100° C., more preferably in the range of 10 to 90° C., or still more preferably in the range of 15 to 80° C., though it is depending on the kinds of the reaction solvent and of the extraction solvent to be removed. Degree of the vacuum in this operation is preferably an atmospheric pressure or lower, more preferably 80 kPa or lower in the absolute pressure, or still more preferably 50 kPa or lower in the absolute pressure, though it depends on the kinds of the extraction solvent to be removed, of an exhausting equipment, and of a condensation equipment, as well as heating temperature.

In this operation, sometimes the polysiloxane may become unstable because of change of the solvent. This occurs due to compatibility of the polysiloxane with the final solvent; and thus, in order to prevent this from occurring, an ingredient mentioned later may be added as the stabilizer thereof. Adding amount thereof is in the range of 0 to 25 parts by mass, preferably in the range of 0 to 15 parts by mass, or more preferably in the range of 0 to 5 parts by mass, or 0.5 parts or more by mass when it is added, relative to 100 parts by mass of the polysiloxane contained in the solution before the solvent exchange. The solvent exchange operation may be done, if necessary, by adding a stabilizer into the solution before the solvent exchange (this stabilizer will be mentioned later).

There is a risk that the polysiloxane undergoes a condensation reaction further when it is concentrated beyond a certain concentration level whereby changing to the state that it cannot be dissolved into an organic solvent again. And therefore, it is preferable that the compound be kept in the state of solution with proper concentration. However, if the concentration thereof is too dilute, amount of the solvent becomes excessively large; and thus, this is uneconomical. The concentration thereof at this time is preferably in the range of 0.1 to 20% by mass.

A preferable solvent finally added to the polysiloxane solution is an alcoholic solvent; and especially preferable solvents thereof are monoalkyl ether derivatives of ethylene glycol, diethylene glycol, triethylene glycol, propylene glycol, dipropylene glycol, butanediol, and so on. Specific example of the preferable solvent includes butanediol monomethyl ether, propylene glycol monomethyl ether, ethylene glycol monomethyl ether, butanediol monoethyl ether, propylene glycol monoethyl ether, ethylene glycol monoethyl ether, butanediol monopropyl ether, propylene glycol monopropyl ether, and ethylene glycol monopropyl ether.

In addition, if these solvents are a main solvent, a non-alcoholic solvent may be added thereinto as an adjuvant solvent. Illustrative example of this adjuvant solvent includes acetone, tetrahydrofuran, toluene, hexane, ethyl acetate, cyclohexanone, methyl amyl ketone, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, t-butyl acetate, t-butyl propionate, propylene glycol mono-t-butyl ether acetate, γ-butyrolactone, methyl isobutyl ketone, and cyclopentyl methyl ether.

In an alternative operational procedure for the reaction, the hydrolysis reaction is started by adding water or a water-containing organic solvent into a monomer or a monomer-containing organic solution. In this operation, the catalyst may be added into the monomer or the monomer-containing organic solution, or into water or the water-containing organic solvent. The reaction temperature is in the range of 0 to 100° C., or preferably in the range of 10 to 80° C. A method, wherein the temperature thereof is kept in the temperature range of 10 to 50° C. during the time of dropwise addition of water, and then, ageing is done in the temperature range of 20 to 80° C., is preferable.

In the case that the organic solvent is used, a water-soluble solvent is preferable. Illustrative example thereof includes methanol, ethanol, 1-propanol, 2-propanol, 1-butanol, 2-butanol, 2-methyl-1-propanol, acetone, tetrahydrofuran, and acetonitrile; a polyol condensation derivative such as butanediol monomethyl ether, propylene glycol monomethyl ether, ethylene glycol monomethyl ether, butanediol monoethyl ether, propylene glycol monoethyl ether, ethylene glycol monoethyl ether, butanediol monopropyl ether, propylene glycol monopropyl ether, ethylene glycol monopropyl ether, propylene glycol dimethyl ether, diethylene glycol dimethyl ether, propylene glycol monomethyl ether acetate, propylene glycol monoethyl ether acetate, and propylene glycol monopropyl ether; and a mixture of these solvents.

Use amount of these organic solvents may be the same as before. Additional treatment of the reaction mixture thus obtained is done in a manner similar to those mentioned before; and by so doing, the polysiloxane can be obtained.

Alternatively, the polysiloxane used in the present invention may be produced by carrying out the hydrolysis-condensation of a monomer in the presence of a base catalyst. Illustrative example of the base catalyst used in this reaction includes methylamine, ethylamine, propylamine, butylamine, ethylene diamine, hexamethylene diamine, dimethylamine, diethylamine, ethyl methyl amine, trimethylamine, triethylamine, tripropylamine, tributylamine, cyclohexylamine, dicyclohexylamine, monoethanol amine, diethanol amine, dimethyl monoethanol amine, monomethyl diethanol amine, triethanol amine, diazabicyclooctane, diazabicyclononene, diazabicycloundecene, hexamethylene tetramine, aniline, N,N-dimethylaniline, pyridine, N,N-dimethylaminopyridine, pyrrole, piperazine, pyrrolidine, piperidine, picoline, tetramethyl ammonium hydroxide, cholin hydroxide, tetrapropyl ammonium hydroxide, tetrabutyl ammonium hydroxide, ammonia, lithium hydroxide, sodium hydroxide, potassium hydroxide, barium hydroxide, and calcium hydroxide. Use amount of the catalyst is in the range of 10⁻⁶ to 10 moles, preferably in the range of 10⁻⁵ to 5 moles, or more preferably in the range of 10⁻⁴ to 1 mole, relative to 1 mole of a silicon monomer.

Amount of water to obtain the polysiloxane by the hydrolysis-condensation reaction of these monomers is preferably in the range of 0.1 to 50 moles, relative to 1 mole of the hydrolysable substituent group which is bonded to the monomers. The adding amount of more than 50 moles only leads to excessively large equipment for the reaction, so that this is uneconomical.

In this operational procedure, the hydrolysis-condensation reaction is started by adding a monomer into a aqueous catalyst solution. At this time, an organic solvent may be added in the aqueous catalyst solution, or the monomer may be diluted by the organic solvent, or both of them may be conducted. The reaction temperature is in the range of 0 to 100° C., or preferably in the range of 5 to 80° C. A method, wherein the temperature thereof is kept in the temperature range of 5 to 80° C. during the time of dropwise addition of the monomer, and then, ageing is done in the temperature range of 20 to 80° C., is preferable.

Preferable organic solvents which can be added to the aqueous base catalyst solution or can dilute the monomer are similar to those mentioned as the examples of the organic solvent which can be added into the aqueous acid catalyst solution. Meanwhile, use amount of the organic solvent is preferably in the range of 0 to 1000 mL relative to 1 mole of the monomer because the reaction can be carried out economically.

Thereafter, if necessary, a neutralization reaction of the catalyst is carried out, and then, an alcohol formed by the hydrolysis-condensation reaction is removed to obtain an aqueous reaction mixture solution. At this time, use amount of an acidic substance for neutralization is preferably in the range of 0.1 to 2 equivalents relative to the basic substance used as the catalyst. Any acidic substance may be used that shows an acidic property in water.

Then, it is preferable to remove from the reaction mixture a byproduct such as an alcohol produced by the hydrolysis-condensation reaction. Temperature to heat the reaction mixture in this operation is preferably in the range of 0 to 100° C., more preferably in the range of 10 to 90° C., or still more preferably in the range of 15 to 80° C., though it depends on the kinds of an added organic solvent and an alcohol produced by the reaction. Degree of the vacuum in this operation is preferably an atmospheric pressure or lower, more preferably 80 kPa or lower in the absolute pressure, or still more preferably 50 kPa or lower in the absolute pressure, though it depends on the kinds of an organic solvent, an alcohol, and so forth to be removed, of an exhausting equipment, and of a condensation equipment, as well as heating temperature. Although it is difficult to know exactly an amount of the alcohol removed, it is preferable that about 80% or more by mass of a produced alcohol and so forth be removed.

Then, to remove the catalyst used in the hydrolysis-condensation reaction, the polysiloxane is extracted by an organic solvent. At this time, an organic solvent which can dissolve the polysiloxane while can be separated into two layers when mixed with water is preferably used.

In addition, a mixture of a water-soluble organic solvent with a water-insoluble organic solvent may also be used.

The specific examples of the organic solvent to be used in removal of the base catalyst are the same as the specific examples of the afore-mentioned organic solvent to be used in removal of the acid catalyst; and the same is applied for the mixture of the water-soluble organic solvent and the water-insoluble organic solvent.

Meanwhile, mixing ratio of the water-soluble organic solvent to the water-insoluble organic solvent is arbitrarily selected, while the amount of the water-soluble organic solvent is in the range of 0.1 to 1000 parts by mass, preferably in the range of 1 to 500 parts by mass, or more preferably in the range of 2 to 100 parts by mass, relative to 100 parts by mass of the water-insoluble organic solvent.

Then, washing is done by using neutral water. As to the water, so-called de-ionized water or ultrapure water may be used. Amount of this water is in the range of 0.01 to 100 liters, preferably in the range of 0.05 to 50 liters, or more preferably in the range of 0.1 to 5 liters, relative to 1 liter of the polysiloxane solution. This washing operation may be done in such a way that the both solutions are mixed in a vessel by agitation, and then settled to separate a water layer. Number of washing may be 1 time or more, though the range of about 1 to about 5 times is preferable, because washing of 10 times or more is not worth to have full effects thereof.

To the polysiloxane solution after washing is added a final solvent, and then solvents therein are exchanged under reduced pressure to obtain the polysiloxane solution. Temperature at the time of the solvent exchange is preferably in the range of 0 to 100° C., more preferably in the range of 10 to 90° C., or still more preferably in the range of 15 to 80° C., though it depends on the kind of the extraction solvent to be removed. Degree of the vacuum in this operation is preferably an atmospheric pressure or lower, more preferably 80 kPa or lower in the absolute pressure, or still more preferably 50 kPa or lower in the absolute pressure, though it depends on the kinds of the extraction solvent to be removed, of an exhausting equipment, and of a condensation equipment, as well as heating temperature.

A preferable solvent finally added to the polysiloxane solution is an alcoholic solvent; and especially preferable solvents thereof are a monoalkyl ether of ethylene glycol, diethylene glycol, triethylene glycol, and so on; and a monoalkyl ether of propylene glycol, dipropylene glycol, and so on. Specific example of the preferable solvent includes propylene glycol monomethyl ether, ethylene glycol monomethyl ether, propylene glycol monoethyl ether, ethylene glycol monoethyl ether, propylene glycol monopropyl ether, and ethylene glycol monopropyl ether.

In an alternative operational procedure for the reaction, the hydrolysis reaction is started by adding water or a water-containing organic solvent into a monomer or a monomer-containing organic solution. In this operation, the catalyst may be added into the monomer or the monomer-containing organic solution, or into water or the water-containing organic solvent. The reaction temperature is in the range of 0 to 100° C., or preferably in the range of 10 to 80° C. A method, wherein the temperature thereof is kept in the temperature range of 10 to 50° C. during the time of dropwise addition of water, and then, ageing is done in the temperature range of 20 to 80° C., is preferable.

When the organic solvent is used, a water-soluble solvent is preferable. Illustrative example thereof includes methanol, ethanol, 1-propanol, 2-propanol, 1-butanol, 2-butanol, 2-methyl-1-propanol, acetone, tetrahydrofuran, and acetonitrile; a polyol condensation derivative such as propylene glycol monomethyl ether, ethylene glycol monomethyl ether, propylene glycol monoethyl ether, ethylene glycol monoethyl ether, propylene glycol monopropyl ether, ethylene glycol monopropyl ether, propylene glycol dimethyl ether, diethylene glycol dimethyl ether, propylene glycol monomethyl ether acetate, propylene glycol monoethyl ether acetate, and propylene glycol monopropyl ether; and a mixture of these solvents.

Molecular weight of the obtained polysiloxane can be adjusted not only by selection of the monomer but also by control of reaction conditions during the time of polymerization, wherein the weight-average molecular weight thereof is preferably 100000 or less, more preferably in the range of 200 to 50000, or still more preferably in the range of 300 to 30000, because a foreign matter or a coating smear may be formed as the case may be if the weight-average molecular weight of more than 100,000 is used. Meanwhile, the data of the weight-average molecular weight are of the polystyrene-equivalent molecular weight based on the standard polystyrene, wherein the data are obtained by a gel permeation chromatography (GPC) using RI as a detector and tetrahydrofuran as an eluting solvent.

To improve stability of the polysiloxane-containing resist underlayer film forming composition of the present invention, it is preferable to add thereinto an organic acid having 1 to 30 carbon atoms with the valency thereof being one, or two or higher. Illustrative example of the acid to be added therein includes formic acid, acetic acid, propionic acid, butanoic acid, pentanoic acid, hexanoic acid, heptanoic acid, octanoic acid, nonanoic acid, decanoic acid, oleic acid, stearic acid, linoleic acid, linolenic acid, benzoic acid, phthalic acid, isophthalic acid, terephthalic acid, salicylic acid, trifluoroacetic acid, monochloroacetic acid, dichloroacetic acid, trichloroacetic acid, oxalic acid, malonic acid, methylmalonic acid, ethylmalonic acid, propylmalonic acid, butylmalonic acid, dimethylmalonic acid, diethylmalonic acid, succinic acid, methylsuccinic acid, glutaric acid, adipic acid, itaconic acid, maleic acid, fumaric acid, citraconic acid, and citric acid. Especially, oxalic acid, maleic acid, formic acid, acetic acid, propionic acid, citric acid, and the like are preferable. To keep the stability, two or more kinds of these acids may be used as a mixture. Adding amount thereof is in the range of 0.001 to 25 parts by mass, preferably in the range of 0.01 to 15 parts by mass, or more preferably in the range of 0.1 to 5 parts by mass, relative to 100 parts by mass of the polysiloxane contained in the composition.

Alternatively, the above-mentioned organic acid is added such that pH of the composition may become preferably 0≦pH≦7, more preferably 0.3≦pH≦6.5, or still more preferably 0.5≦pH≦6.

In the present invention, water may be added to the composition. When water is added thereinto, the polysiloxane is hydrated whereby improving a lithography performance. Water content in the solvent component of the composition is more than 0% by mass and less than 50% by mass, especially preferably in the range of 0.3 to 30% by mass, or still more preferably in the range of 0.5 to 20% by mass. If the adding amount of each component is too much, uniformity of the coat film is deteriorated, whereby causing a fish eye in the worst case. On the other hand, if the adding amount is too small, the lithography performance deteriorates so that this is not desirable.

Use amount of entirety of the solvent including water is preferably in the range of 100 to 100000 parts by mass, or especially preferably in the range of 200 to 50000 parts by mass, relative to 100 parts by mass of the base polymer.

In the composition of the present invention, a photo-sensitive acid generator may be used. Specific example of the photo-sensitive acid generator that can be used in the present invention includes those materials described in the paragraphs of (0118) to (0119) of Japanese Patent Laid-Open Publication No. 2009-126940.

In addition, as a stabilizer, an alcohol having a cyclic ether substituent with the valency thereof being one, or two or higher, may be added to the polysiloxane-containing resist underlayer film forming composition to enhance the stability thereof. Specifically, those materials described in paragraphs (0121) to (0122) of Japanese Patent Laid-Open Publication No. 2009-126940 may be added thereinto.

Further, in the present invention, a surfactant may be added to the composition, if necessary. Specifically, those materials described in paragraph (0124) of Japanese Patent Laid-Open Publication No. 2009-126940 may be added thereinto.

Similarly to the photoresist film, the polysiloxane-containing resist underlayer film used in the patterning process of the present invention can be formed on the body to be processed by a spin coating method and so on from the polysiloxane-containing resist underlayer film forming composition. After spin coating, the solvent is evaporated, and then it is preferable to carry out baking for facilitating the crosslinking reaction to prevent mixing with the upper layer resist film from occurring. This baking is carried out preferably in the temperature range of 50 to 500° C. and the time range of 10 to 300 seconds. In order to lower the damage to a device, especially preferable temperature range is 400° C. or lower, though depending on the structure of the device to be manufactured.

Use of the polysiloxane-containing resist underlayer film as mentioned above can afford excellent adhesion with the resist pattern formed on the polysiloxane-containing resist underlayer film while showing further higher dry etching selectivity between the photoresist film, which is the upper layer of the polysiloxane-containing resist underlayer film, and the organic film formed thereunder.

As to the body to be processed, a semiconductor device substrate or a semiconductor substrate coated with, as the layer to be processed (the part to be processed), any of a metal film, a metal carbide film, a metal oxide film, a metal nitride film, and a metal oxynitride film may be used.

As to the semiconductor substrate, a silicon substrate is generally used, however, it is not particularly restricted; and thus, a material that is different from the layer to be processed, such as Si, amorphous silicon (α-Si), p-Si, SiO₂, SiN, SiON, W, TiN, Al, and so on may be used.

The metal that constitutes the body to be processed may be any of silicon, titanium, tungsten, hafnium, zirconium, chromium, germanium, copper, aluminum, indium, gallium, arsenic, palladium, iron, tantalum, iridium, molybdenum, or an alloy of them. Illustrative example of the layer to be processed which contains these metals includes layers of Si, SiO₂, SiN, SiON, SiOC, p-Si, α-Si, TiN, WSi, BPSG, SOG, Cr, CrO, CrON, MoSi, W, W—Si, Al, Cu, Al—Si, various low dielectric film, and its etching stopper film. Here, the film may be formed with the thickness of usually in the range of 50 to 10000 nm, in particular in the range of 100 to 5000 nm.

As to the resist patterning process, the directed self-assembly method (DSA method) or the nanoimprinting lithography method may be used.

The resist pattern may be formed by a method wherein a photoresist film is formed by using a chemically amplified resist composition, the photoresist film is exposed by a high energy beam after heat treatment, and then, the exposed part of the photoresist film is dissolved by using an alkaline developing solution to form a positive pattern; or alternatively, the resist pattern may be formed by a method wherein a photoresist film is formed by using a chemically amplified resist composition, the photoresist film is exposed by a high energy beam after heat treatment, and then, the unexposed part of the photoresist film is dissolved by using an organic solvent developing solution to form a negative pattern.

In the patterning process of the present invention, the upper layer photoresist film is not particularly restricted, provided that it is of the chemically amplified type which can form a negative pattern by development with an organic solvent developer, or can form a positive pattern.

As the lithography method using the high energy beam, a lithography method using a light having the wavelength of 300 nm or less, a lithography method using an EUV light, or an electron beam direct drawing method may be used.

The exposure process of the present invention may be done by the exposure process using an ArF excimer laser beam; and in this case, any usual resist composition for the ArF excimer laser beam may be used for the upper layer photoresist film.

There are many already known candidates for the resist composition for the ArF excimer laser beam, wherein the already known resins may be classified roughly into a poly(meth)acrylate type, a COMA (Cyclo Olefin Maleic Anhydride) type, a COMA-(meth)acryl hybrid type, a ROMP (Ring Opening Metathesis Polymerization) type, a polynorbornene type, and so forth. Among them, the resist composition using a poly(meth)acrylate type resin secures the etching resistance by introducing an alicyclic skeleton into a side chain thereof; and thus, this has a superior resolution performance as compared with other resin types.

By using the patterning process of the present invention, a fine pattern can be formed on the substrate with high precision.

### EXAMPLES

Hereunder, the present invention will be explained specifically by showing Examples and Comparative Examples, but the present invention is not restricted by those descriptions. Meanwhile, in the following examples, “%” means “% by mass”; and measurement of the molecular weight was based on GPC.

### Synthesis Examples of Thermal Crosslinking Accelerators:

Triphenylsulfonium tetraphenylborate (Accelerator 1)

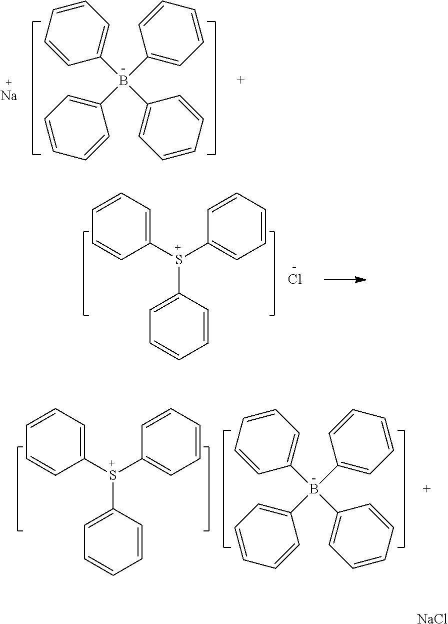

Into a mixture of 200 g of dichloromethane and 250 g of de-ionized water were added 10.0 g of sodium tetraphenylborate and 9.2 g of triphenylsulfonium chloride; and then, the resulting mixture was stirred at room temperature for 24 hours to carry out the ion-exchange reaction. After completion of the reaction, the water layer was removed by separation, 250 g of de-ionized water was further added; and then, this mixture was stirred, settled, and then separated into the layers. The obtained organic layer was concentrated by a rotary evaporator; and the obtained crystals were purified by recrystallization from dipropyl ether to obtain 14.6 g of white crystals (yield 86%).

As to the following tetraphenylborate compounds, commercially available products were used.

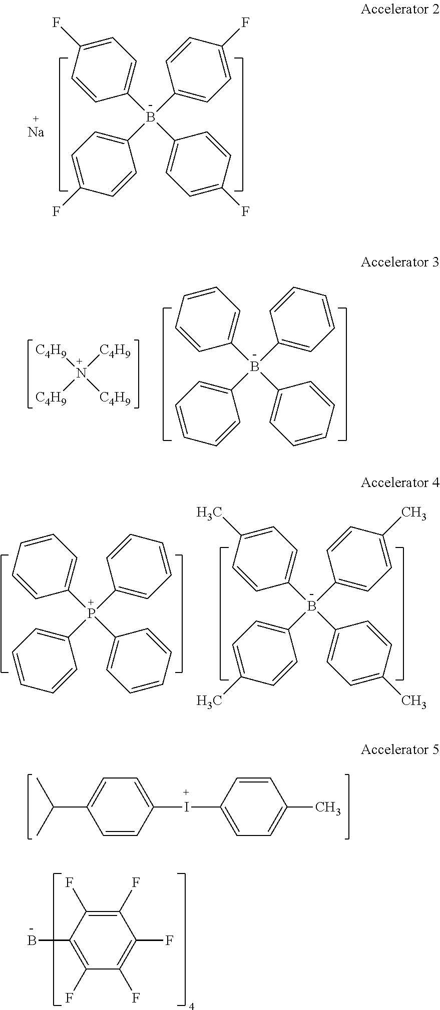

### Synthesis of Polysiloxanes

### Synthesis Example 1

Into a mixture of 400 g of ethanol, 0.2 g of methanesulfonic acid, and 120 g of de-ionized water was added a mixture of 9.9 g of phenyl trimethoxy silane and 197.9 g of tetraethoxy silane; and then, the resulting mixture was kept at 40° C. for 12 hours to carry out the hydrolysis-condensation reaction. After completion of the reaction, 800 g of propylene glycol ethyl ether (PGEE) was added; and then, the bi-produced alcohols and excessive water were removed by distillation under reduced pressure to obtain 750 g of PGEE solution of Polysiloxane 1 (compound concentration of 11.5%). The polystyrene-equivalent molecular weight of this product was measured to be Mw=2550.

### Synthesis Example 2

Into a mixture of 400 g of ethanol, 0.2 g of methanesulfonic acid, and 120 g of de-ionized water was added a mixture of 11.9 g of phenyl trimethoxy silane and 195.8 g of tetraethoxy silane; and then, the resulting mixture was kept at 40° C. for 12 hours to carry out the hydrolysis-condensation reaction. After completion of the reaction, 800 g of propylene glycol ethyl ether (PGEE) was added; and then, the bi-produced alcohols and excessive water were removed by distillation under reduced pressure to obtain 750 g of PGEE solution of Polysiloxane 2 (compound concentration of 11.7%). The polystyrene-equivalent molecular weight of this product was measured to be Mw=2500.

### Synthesis Example 3

Into a mixture of 400 g of ethanol, 0.2 g of methanesulfonic acid, and 120 g of de-ionized water was added a mixture of 13.9 g of phenyl trimethoxy silane and 193.7 g of tetraethoxy silane; and then, the resulting mixture was kept at 40° C. for 12 hours to carry out the hydrolysis-condensation reaction. After completion of the reaction, 800 g of propylene glycol ethyl ether (PGEE) was added; and then, the bi-produced alcohols and excessive water were removed by distillation under reduced pressure to obtain 750 g of PGEE solution of Polysiloxane 3 (compound concentration of 11.5%). The polystyrene-equivalent molecular weight of this product was measured to be Mw=2500.

### Examples and Comparative Examples

Each of the polysiloxanes obtained by the Synthesis Examples was mixed with the solvent and the crosslinking accelerator according to the ratio shown in Table 1; and then, the resulting mixture was filtrated through a 0.1-μm filter made of a fluororesin to obtain each of the polysiloxane-containing resist underlayer film forming composition solutions assigned to Sol. 1 to Sol. 9.

TABLE 1

| | Polysiloxane | Crosslinking | | Additive |
|---|---|---|---|---|
| | (parts by | accelerator | Solvent | (parts by |
| No. | mass) | (parts by mass) | (parts by mass) | mass) |
| Sol. 1 | 1 (4.0) | Accelerator 1 (0.026) | PGEE (140) | H₂O (10) |
| Sol. 2 | 1 (4.0) | Accelerator 2 (0.033) | PGEE (140) | H₂O (10) |
| Sol. 3 | 1 (4.0) | Accelerator 3 (0.044) | PGEE (140) | H₂O (10) |
| Sol. 4 | 1 (4.0) | Accelerator 4 (0.028) | PGEE (140) | H₂O (10) |
| Sol. 5 | 1 (4.0) | Accelerator 5 (0.054) | PGEE (140) | H₂O (10) |
| Sol. 6 | 2 (4.0) | TPSMA (0.040) | PGEE (140) | H₂O (10) |
| Sol. 7 | 1 (4.0) | None | PGEE (140) | H₂O (10) |
| Sol. 8 | 2 (4.0) | None | PGEE (140) | H₂O (10) |
| Sol. 9 | 3 (4.0) | None | PGEE (140) | H₂O (10) |

TPSMA: mono(triphenylsulfonium) maleic acid

Each of Sol. 1 to Sol. 9 was applied by a spin coating method, and then, it was heated at 200° C. for 1 minute to form the polysiloxane . . . containing film having the film thickness of 40 nm (assigned to Film 1 to Film 9). The optical constants (refractive index “n” and extinction coefficient “k”) of Film 1 to Film 9 were measured at the wavelength of 193 nm by using a spectroscopic ellipsometer with a variable incident light angle (VUV-VASE, manufactured by J. A. Woollam Co., Inc.). The results thereof are shown in Table 2.

TABLE 2

| No. | Refractive index: n | Extinction coefficient: k |
|---|---|---|
| Film 1 | 1.62 | 0.18 |
| Film 2 | 1.62 | 0.18 |
| Film 3 | 1.62 | 0.18 |
| Film 4 | 1.62 | 0.18 |
| Film 5 | 1.62 | 0.18 |
| Film 6 | 1.62 | 0.18 |
| Film 7 | 1.61 | 0.14 |
| Film 8 | 1.61 | 0.16 |
| Film 9 | 1.62 | 0.18 |

Formation of the polysiloxane-containing film having the ratio, refractive index/extinction coefficient=1.62/0.18, is achievable in the combination of the polysiloxane of Example 1 with the novel crosslinking accelerator (Film 1 to Film 5), in the combination of the polysiloxane of Example 2 with the heretofore known crosslinking accelerator (Film 6), and in the polysiloxane of Example 3 (without crosslinking accelerator, Film 9).

### Etching Test:

The coat film formed by the above test was dry etched under the following condition (1) or condition (2) to obtain the etching rates.

(1) Etching condition in the CHF₃/CF₄ type gas
Instrument: dry etching instrument Telius SP (manufactured by Tokyo Electron Ltd.)

### Etching Condition (1):

| | |
|---|---|
| Chamber pressure | 10 Pa |
| Upper/lower RF power | 500 W/300 W |
| CHF₃ gas flow rate | 50 mL/minute |
| CF₄ gas flow rate | 150 mL/minute |
| Ar gas flow rate | 100 mL/minute |
| Treatment time | 40 seconds |

(2) Etching condition in the O₂/N₂ type gas
Instrument: dry etching instrument Telius SP (manufactured by Tokyo Electron Ltd.)

### Etching Condition (2):

| | |
|---|---|
| Chamber pressure | 2 Pa |
| Upper/lower RF power | 1000 W/300 W |
| O₂ gas flow rate | 300 mL/minute |
| N₂ as flow rate | 100 mL/minute |
| Ar gas flow rate | 100 mL/minute |
| Treatment time | 30 seconds |

TABLE 3

| | | CF Etching rate | O₂/N₂ Etching rate |
|---|---|---|---|
| No. | Film | (nm/minute) | (nm/minute) |
| Example 1 | Film 1 | 63 | 3 |
| Example 2 | Film 2 | 63 | 3 |
| Example 3 | Film 3 | 63 | 3 |
| Example 4 | Film 4 | 63 | 3 |
| Example 5 | Film 5 | 63 | 3 |
| Comparative Example 1 | Film 6 | 60 | 3 |
| Comparative Example 2 | Film 7 | 64 | 3 |
| Comparative Example 3 | Film 8 | 61 | 4 |
| Comparative Example 4 | Film 9 | 58 | 5 |

From the comparison among Comparative Example 2, Comparative Example 3, and Comparative Example 4, it was found that a polymer having a higher k-value showed a slower CF etching rate. This may be attributed to large amount of the introduced benzene ring to absorb the 193-nm UV beam in the polysiloxanes used in Comparative Example 3 and Comparative Example 4.

In order to obtain the silicon-containing films having the same k-value by using two polysiloxanes having different k-values, adding amount of the crosslinking accelerator was adjusted to obtain Film 1 to Film 6. As a result, it was found that a combination of the crosslinking accelerator of the present invention with the polysiloxane having a low k-value showed a faster CF etching rate as compared with a combination of the conventional crosslinking accelerator with the polysiloxane having a high k-value. This may be attributed to that the organic group directly bonded to the polysiloxane has a large influence to the CF etching rate, while the organic group not directly bonded to the polysiloxane but added as the additive does not have much influence to the CF etching rate.

### Patterning Test:

The spin-on-carbon film ODL-50 (carbon content of 80% by mass, manufactured by Shin-Etsu Chemical Co., Ltd.) having the film thickness of 200 nm was formed on a silicon wafer. Then, each of the polysiloxane-containing resist underlayer film forming compositions Sol. 1 to Sol. 5 and Sol. 9 was applied thereonto; and then, it was baked at 240° C. for 60 seconds to form the polysiloxane-containing film having the film thickness of 35 nm (Film 1 to Film 5 and Film 9).

Then, the ArF resist solution for the positive development (PR-1) shown in Table 4 was applied onto the polysiloxane-containing film; and then, it was baked at 110° C. for 60 seconds to form the photoresist film having the film thickness of 100 nm. On this photoresist film was coated further the immersion top coat (TC-1) shown in Table 5; and then, it was baked at 90° C. for 60 seconds to form the top coat having the film thickness of 50 nm.

Subsequently, these were exposed by using the ArF immersion exposure instrument NSR-S610C (NA of 1.30, a of 0.98/0.65, 35-degree dipole polarized illumination, and 6% half tone phase shift mask; manufactured by Nikon Corp.), baked (PEB) at 1000° C. for 60 seconds, and then developed by the aqueous solution of tetramethylammonium hydroxide (TMAH, concentration of 2.38% by mass) for 30 seconds to obtain the positive 43 nm 1:1 line-and-space pattern.

By this patterning, the negative 43 nm 1:1 line-and-space pattern was obtained. This dimension was measured as to the pattern fall by the electron microscope CG4000 (manufactured by Hitachi High-Technologies Corp.); and as to the cross section form by the electron microscope S-9380 (manufactured by Hitachi, Ltd.) (see, Table 6).

TABLE 4

| | | Acid | | | |
|---|---|---|---|---|---|
| | Polymer | generator | Base | Water-repellent | Solvent |
| | (parts | (parts by | (parts by | polymer | (parts by |
| No. | by mass) | mass) | mass) | (parts by mass) | mass) |
| PR-1 | ArF Resist | PAG 1 | Quencher | None | PGMEA |
| | Polymer 1 | (7.0) | (1.0) | | (2500) |
| | (100) | | | | |

### ArF Resist Polymer 1:

Molecular weight (Mw): 7800

Dispersity (Mw/Mn): 1.78

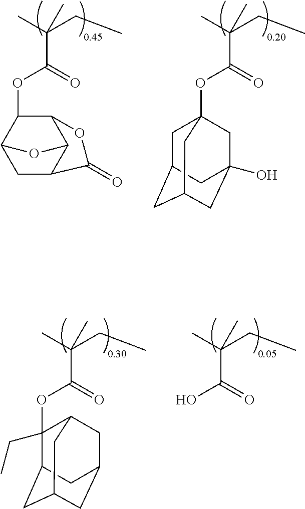

### Acid Generator: PAG 1

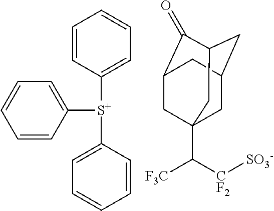

### Basic Compound: Quencher

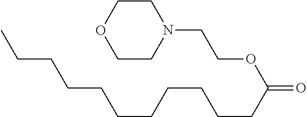 [SMILES: CCCCCCCCCCCC(=O)OCCN1CCOCC1]

### Top Coat Polymer:

Molecular weight (Mw): 8800

Dispersity (Mw/Mn): 1.69

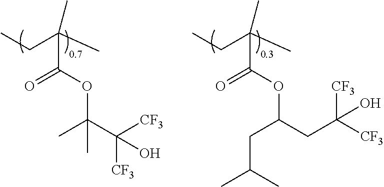

TABLE 5

| | Polymer | Organic solvent |
|---|---|---|
| | (parts by mass) | (parts by mass) |
| TC-1 | Top coat Polymer (100) | Diisoamyl ether (2700) |
| | | 2-Methyl-1-butanol (270) |

### Etching Test:

By using the resist pattern prepared in the above-mentioned patterning test as a mask, dry etching was done according to the following condition (1), and then, dry etching was done according to the following condition (2) to transfer the pattern to the spin-on-carbon film. The cross section form of the obtained pattern was observed by the electron microscope S-9380 (manufactured by Hitachi, Ltd.); and the pattern roughness was measured by the electron microscope CG4000 (manufactured by Hitachi High-Technologies Corp.). The results are shown in the Table 6.

(1) Etching condition in the CHF₃/CF₄ type gas Instrument: dry etching instrument Telius SP (manufactured by Tokyo Electron Ltd.)

### Etching Condition (1):

| | |
|---|---|
| Chamber pressure | 10 Pa |
| Upper/lower RF power | 500 W/300 W |
| CHF₃ gas flow rate | 50 mL/minute |
| CF₄ gas flow rate | 150 mL/minute |
| Ar gas flow rate | 100 mL/minute |
| Treatment time | 40 seconds |

(2) Etching condition in the O₂/N₂ type gas
Instrument: dry etching instrument Telius SP (manufactured by Tokyo Electron Ltd.)

### Etching Condition (2):

| | |
|---|---|
| Chamber pressure | 2 Pa |
| Upper/lower RF power | 1000 W/300 W |
| O₂ gas flow rate | 300 mL/minute |
| N₂ gas flow rate | 100 mL/minute |
| Ar gas flow rate | 100 mL/minute |
| Treatment time | 30 seconds |

TABLE 6

| | | Pattern cross | | Pattern cross | |
|---|---|---|---|---|---|
| | | section form of | | section form of | |
| | Silicon- | upper layer | | spin-on-carbon | |
| | containing | resist after | Pattern | film after dry | Pattern |
| Example | film | development | roughness | etching | roughness |
| Example 1 | Film 1 | Vertical form | 2.7 nm | Vertical form | 2.5 nm |
| Example 2 | Film 2 | Vertical form | 2.6 nm | Vertical form | 2.4 nm |
| Example 3 | Film 3 | Vertical form | 2.6 nm | Vertical form | 2.4 nm |
| Example 4 | Film 4 | Vertical form | 2.6 nm | Vertical form | 2.6 nm |
| Example 5 | Film 5 | Vertical form | 2.8 nm | Vertical form | 2.2 nm |
| Comparative | Film 9 | Vertical form | 2.9 nm | Tapered form | 3.0 nm |
| Example 4 | | | | | |

The resist patterns having the same optical constant after exposure showed almost the same performance. On the other hand, when comparison was made between the polysiloxane-containing film formed of a polymer having in the polymer much amount of an organic group (benzene ring) to absorb the light and the polysiloxane-containing film of the present invention containing small amount of the organic group having the optical constants of the film adjusted by the additive, the polysiloxane-containing film formed by using the additive of the present invention showed better pattern form after dry etching.

It must be noted here that the present invention is not limited to the embodiments as described above. The foregoing embodiments are mere examples; any form having substantially the same composition as the technical concept described in claims of the present invention and showing similar effects is included in the technical scope of the present invention.

What is claimed is:

1. A patterning process, wherein an organic underlayer film is formed on a body to be processed by using a coating-type organic underlayer film forming composition, on the organic underlayer film is formed a polysiloxane-containing resist underlayer film by using a polysiloxane-containing resist underlayer film forming composition, on the polysiloxane-containing resist underlayer film is formed a resist pattern, the pattern is transferred by dry etching to the resist underlayer film by using the resist film having the formed pattern as a mask, the pattern is transferred by dry etching to the organic underlayer film by using the resist underlayer film having the transferred pattern as a mask, and further, the pattern is transferred by dry etching to the body to be processed by using the organic underlayer film having the transferred pattern as a mask;
wherein the polysiloxane-containing resist underlayer film forming composition contains a thermal crosslinking accelerator shown by the following general formula (A-1) and a polysiloxane, the thermal crosslinking accelerator being contained in a range of 0.01 to 40 parts by mass relative to 100 parts by mass of the polysiloxane, 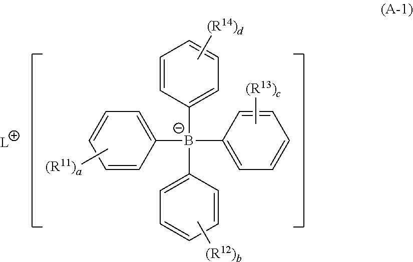
wherein R¹¹, R¹², R¹³, and R¹⁴ each represents a hydrogen atom, a halogen atom, a linear, a branched, or a cyclic alkyl, alkenyl, oxoalkyl, or oxoalkenyl group having 1 to 20 carbon atoms, an optionally substituted aryl group having 6 to 20 carbon atoms, or an aralkyl or an aryloxoalkyl group having 7 to 20 carbon atoms, wherein a part of or all of hydrogen atoms in these groups may be substituted by an alkoxy group, an amino group, an alkylamino group, a halogen atom, or a trimethylsilyl group; “a”, “b”, “c”, and “d” represent an integer of 0 to 5; in the case that “a”, “b”, “c”, and “d” are 2 or more, R¹¹, R¹², R¹³, and R¹⁴ may form a cyclic structure; and character L represents lithium, sodium, potassium, rubidium, cesium, or a counter ion shown by the following general formula (A-2), (A-3), (A-4), or (A-5), 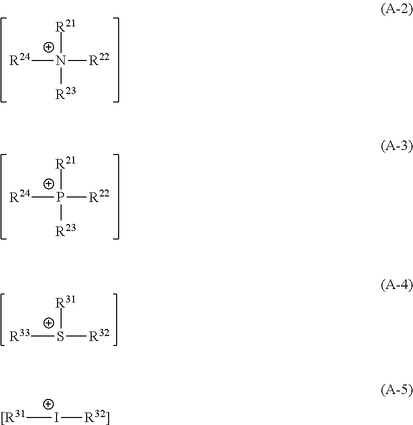
wherein R²¹, R²², R²³, and R²⁴ each represents a linear, a branched, or a cyclic alkyl, alkenyl, oxoalkyl, or oxoalkenyl group having 1 to 20 carbon atoms, an optionally substituted aryl group having 6 to 20 carbon atoms, or an aralkyl or an aryloxoalkyl group having 7 to 12 carbon atoms, wherein a part of or all of hydrogen atoms in these groups may be substituted by a halogen atom, an alkyl group, an alkoxy group, or a trimethylsilyl group; R²¹ and R²², and R²¹, R²², and R²³ may form a ring; and in the case of forming a ring, R²¹ and R²², and R²¹, R²², and R²³ represent an alkylene group having 3 to 10 carbon atoms; R³¹, R³², and R³³ represent the same meanings as R²¹, R²², R²³, and R²⁴, or they may be a hydrogen atom; R³² and R³³ may from a ring; and in the case of forming the ring, R³² and R³³ each represents an alkylene group having 1 to 6 carbon atoms,
wherein the counter ion shown by the general formula (A-3) is an ion selected from the following ions:

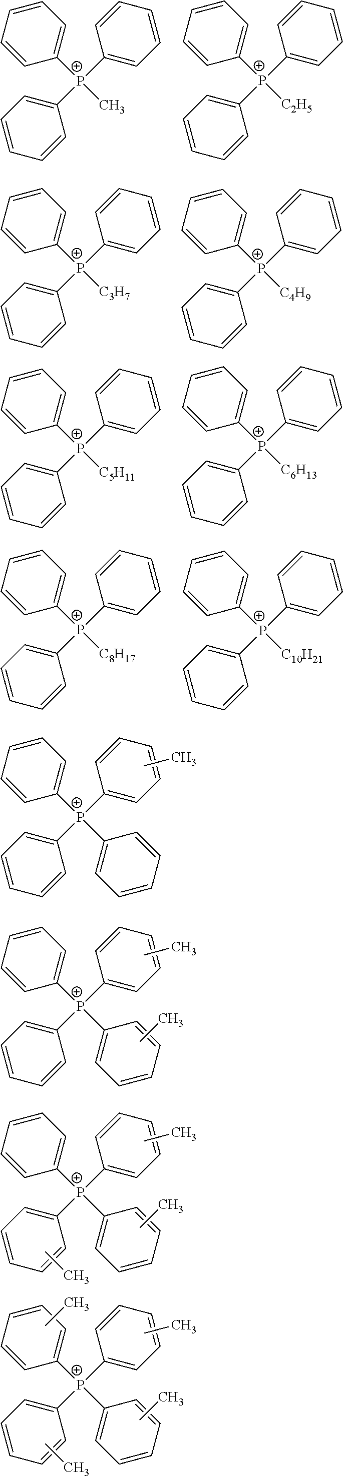

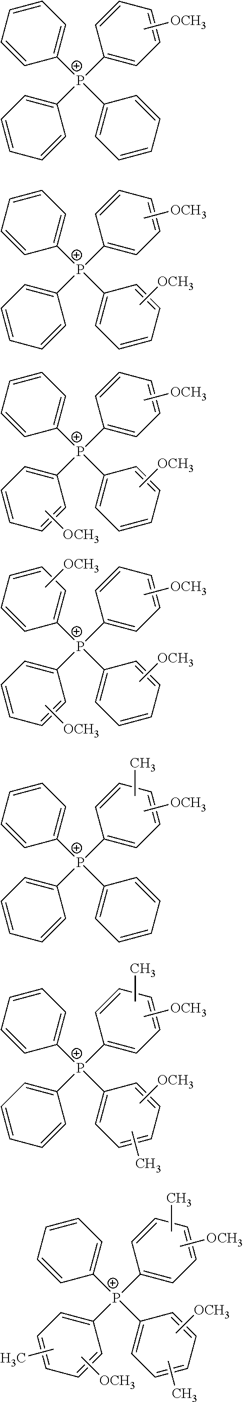

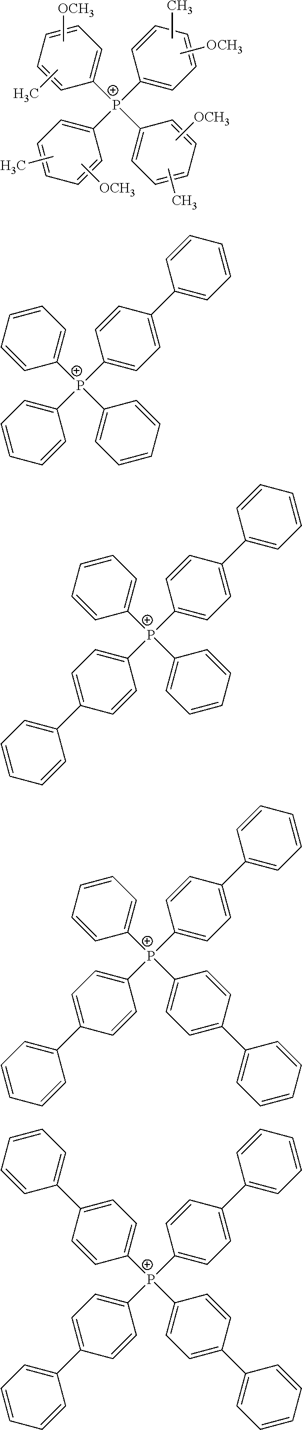

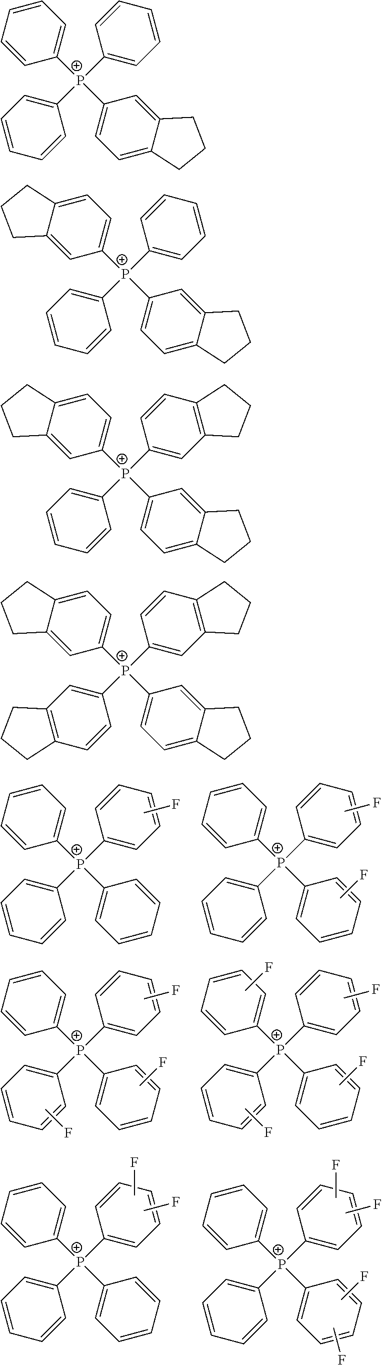

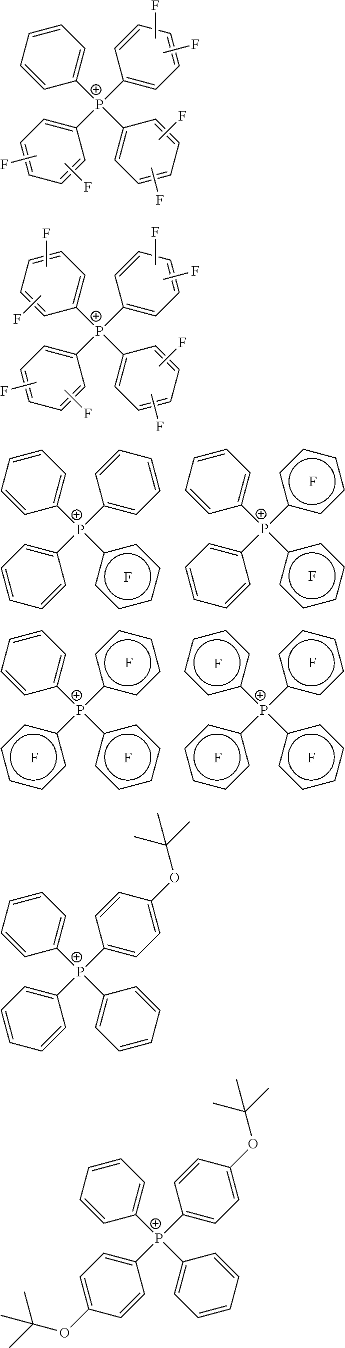

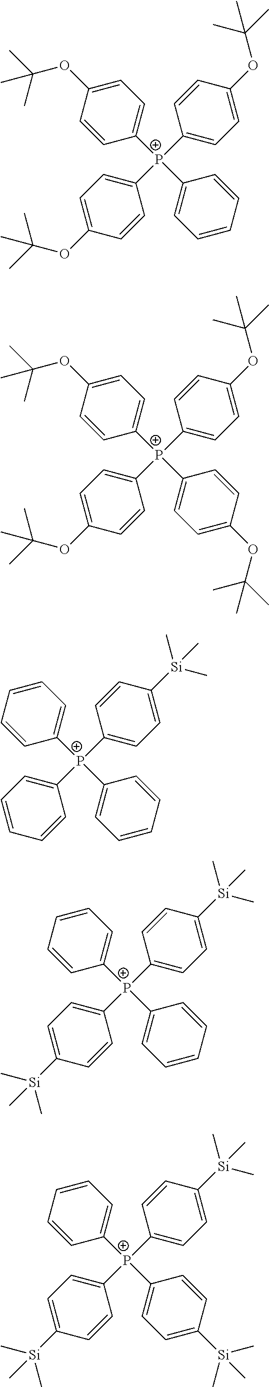

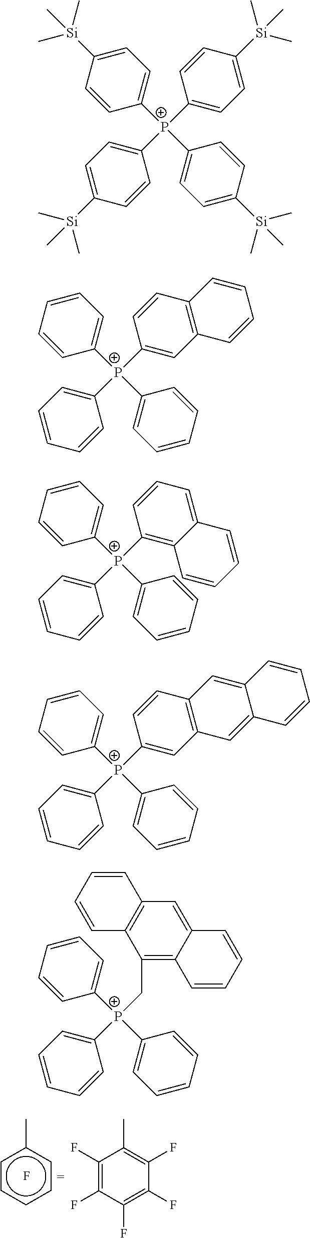

2. A patterning process, wherein an organic hard mask mainly comprising a carbon atom is formed on a body to be processed by using a CVD method, on the organic hard mask is formed a polysiloxane-containing resist underlayer film by using the polysiloxane-containing resist underlayer film forming composition, on the polysiloxane-containing resist underlayer film is formed a resist pattern, the pattern is transferred by dry etching to the resist underlayer film by using the resist film having the formed pattern as a mask, the pattern is transferred by dry etching to the organic hard mask by using the resist underlayer film having the transferred pattern as a mask, and further, the pattern is transferred by dry etching to the body to be processed by using the organic hard mask having the transferred pattern as a mask;
wherein the polysiloxane-containing resist underlayer film forming composition contains a thermal crosslinking accelerator shown by the following general formula (A-1) and a polysiloxane, the thermal crosslinking accelerator being contained in a range of 0.01 to 40 parts by mass relative to 100 parts by mass of the polysiloxane, 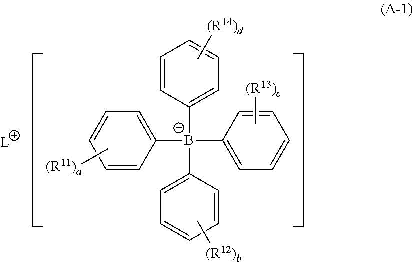
wherein R¹¹, R¹², R¹³, and R¹⁴ each represents a hydrogen atom, a halogen atom, a linear, a branched, or a cyclic alkyl, alkenyl, oxoalkyl, or oxoalkenyl group having 1 to 20 carbon atoms, an optionally substituted aryl group having 6 to 20 carbon atoms, or an aralkyl or an aryloxoalkyl group having 7 to 20 carbon atoms, wherein a part of or all of hydrogen atoms in these groups may be substituted by an alkoxy group, an amino group, an alkylamino group, a halogen atom, or a trimethylsilyl group; “a”, “b”, “c”, and “d” represent an integer of 0 to 5; in the case that “a”, “b”, “c”, and “d” are 2 or more, R¹¹, R¹², R¹³, and R¹⁴ may form a cyclic structure; and character L represents lithium, sodium, potassium, rubidium, cesium, or a counter ion shown by the following general formula (A-2), (A-3), (A-4), or (A-5), 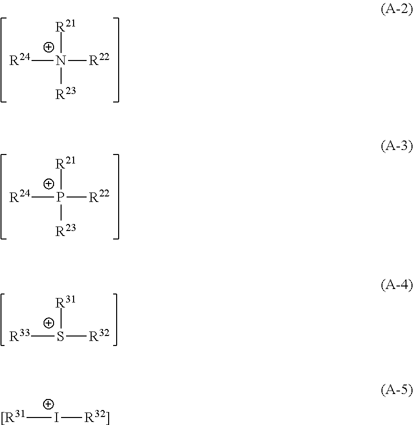
wherein R²¹, R²², R²³, and R²⁴ each represents a linear, a branched, or a cyclic alkyl, alkenyl, oxoalkyl, or oxoalkenyl group having 1 to 20 carbon atoms, an optionally substituted aryl group having 6 to 20 carbon atoms, or an aralkyl or an aryloxoalkyl group having 7 to 12 carbon atoms, wherein a part of or all of hydrogen atoms in these groups may be substituted by a halogen atom, an alkyl group, an alkoxy group, or a trimethylsilyl group; R²¹ and R²², and R²¹, R²², and R²³ may form a ring; and in the case of forming a ring, R²¹ and R²², and R²¹, R²², and R²³ represent an alkylene group having 3 to 10 carbon atoms; R³¹, R³², and R³³ represent the same meanings as R²¹, R²², R²³, and R²⁴, or they may be a hydrogen atom; R³² and R³³ may from a ring; and in the case of forming the ring, R³² and R³³ each represents an alkylene group having 1 to 6 carbon atoms,
wherein the counter ion shown by the general formula (A-3) is an ion selected from the following ions:

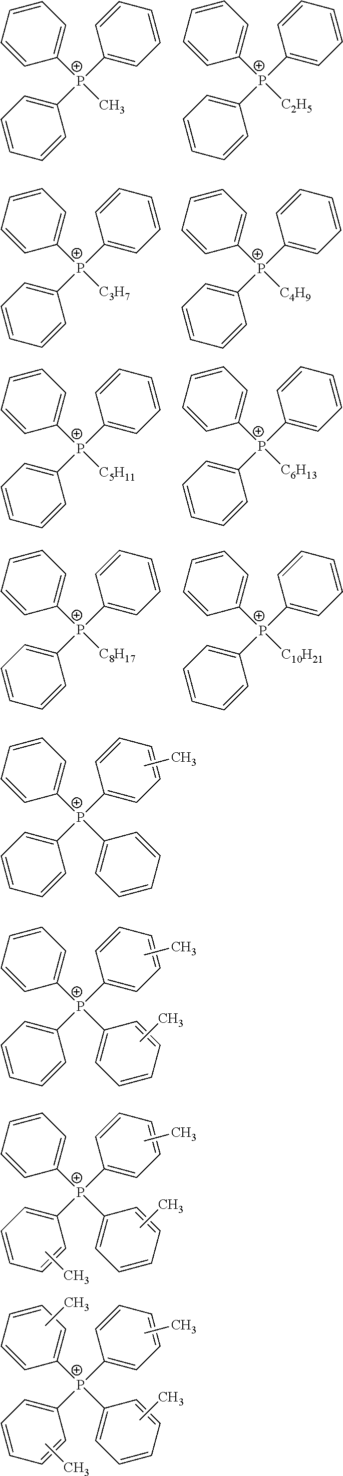

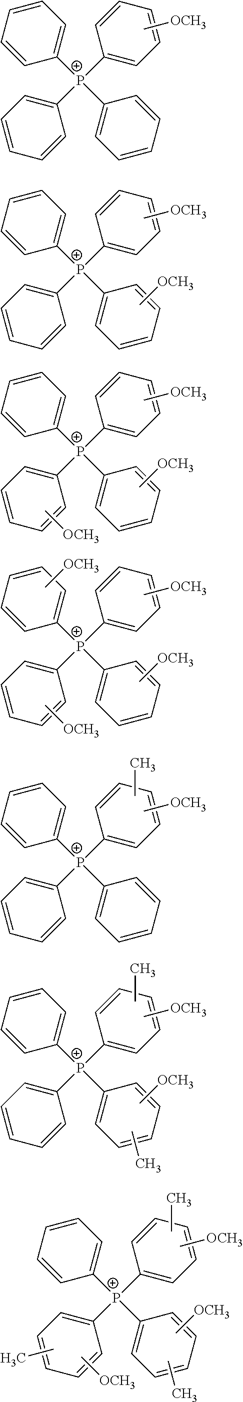

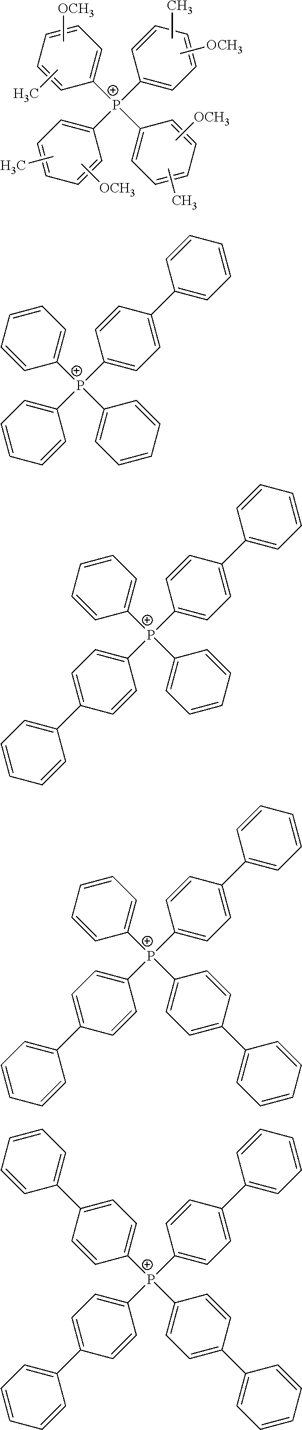

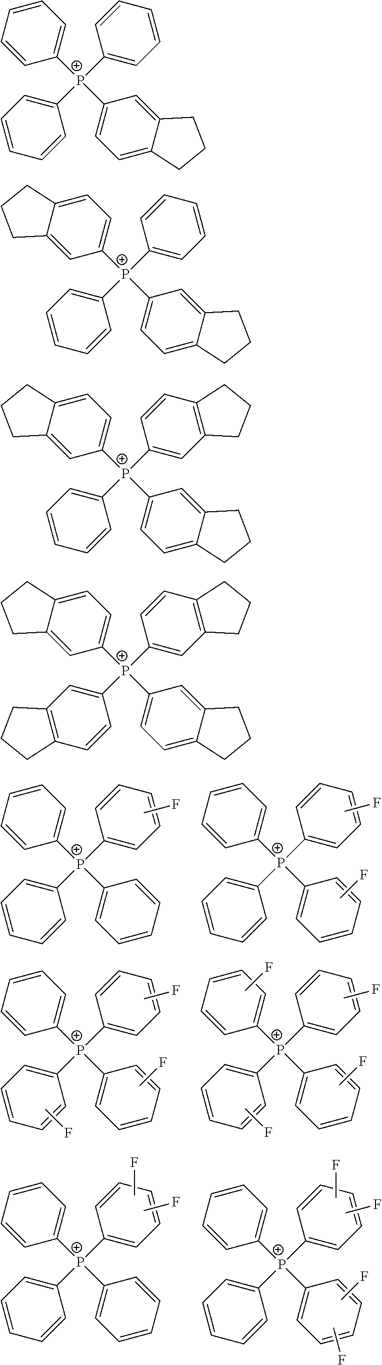

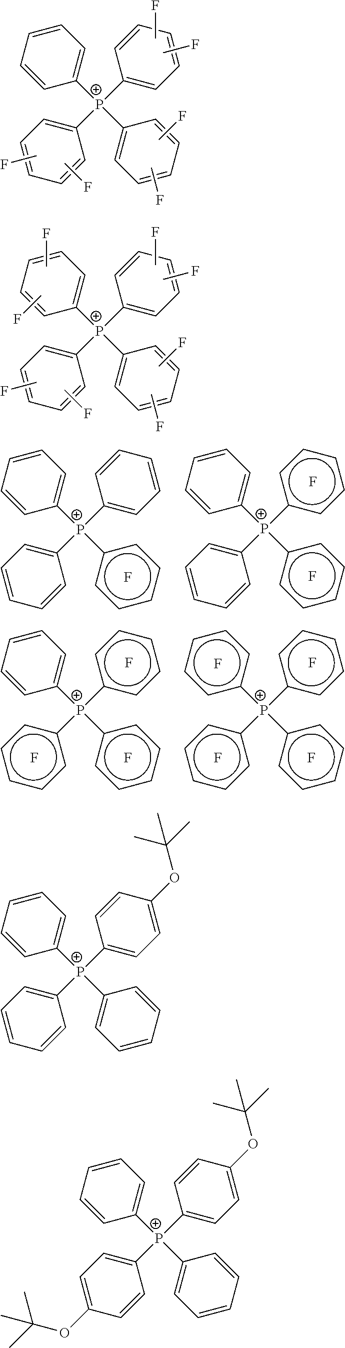

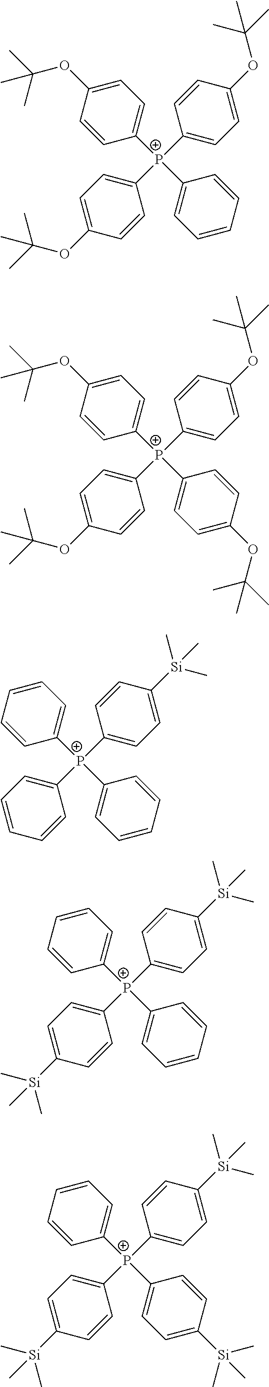

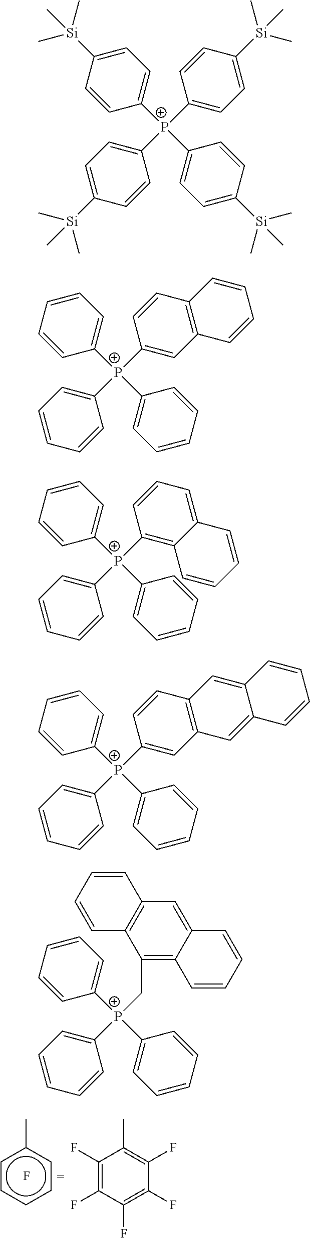

3. A patterning process according to claim 1, wherein the polysiloxane contains one or more compound selected from the group consisting of a compound shown by the following general formula (B-1), a hydrolysate thereof, a condensate thereof, and a hydrolysis-condensate thereof;
R^{1B}_{B1}R^{2B}_{B2}R^{3B}_{B3}Si(OR^{0B})_{(4-B1-B2-B3)} (B-1)
wherein R^{0B} represents a hydrocarbon group having 1 to 6 carbon atoms; R^{1B}, R^{2B}, and R^{3B} represent a hydrogen atom or a monovalent organic group; and B1, B2, and B3 represent 0 or 1, and 0≦B1+B2+B3≦3.6.

4. A patterning process according to claim 2, wherein the polysiloxane contains one or more compound selected from the group consisting of a compound shown by the following general formula (B-1), a hydrolysate thereof, a condensate thereof, and a hydrolysis-condensate thereof;
R^{1B}_{B1}R^{2B}_{B2}R^{3B}_{B3}Si(OR^{0B})_{(4-B1-B2-B3)} (B-1)
wherein R^{0B} represents a hydrocarbon group having 1 to 6 carbon atoms; R^{1B}, R^{2B}, and R^{3B} represent a hydrogen atom or a monovalent organic group; and B1, B2, and B3 represent 0 or 1, and 0≦B1+B2+B3≦3.

5. The patterning process according to claim 1, wherein the body to be processed is a substrate for a semiconductor device, a metal film, a metal carbide film, a metal oxide film, a metal nitride film, a metal oxycarbide film, or a metal oxynitride film.

6. The patterning process according to claim 2, wherein the body to be processed is a substrate for a semiconductor device, a metal film, a metal carbide film, a metal oxide film, a metal nitride film, a metal oxycarbide film, or a metal oxynitride film.

7. The patterning process according to claim 1, wherein the metal to constitute the body to be processed is silicon, titanium, tungsten, hafnium, zirconium, chromium, germanium, copper, aluminum, indium, gallium, arsenic, palladium, iron, tantalum, iridium, molybdenum, or an alloy of them.

8. The patterning process according to claim 2, wherein the metal to constitute the body to be processed is silicon, titanium, tungsten, hafnium, zirconium, chromium, germanium, copper, aluminum, indium, gallium, arsenic, palladium, iron, tantalum, iridium, molybdenum, or an alloy of them.

9. The patterning process according to claim 1, wherein the resist pattern is formed by a directed self-assembly method (DSA method) or a nanoimprinting lithography method.

10. The patterning process according to claim 2, wherein the resist pattern is formed by a directed self-assembly method (DSA method) or a nanoimprinting lithography method.

11. The patterning process according to claim 1, wherein the resist pattern is formed by a method that a photoresist film is formed by using a chemically amplified resist composition, the photoresist film is exposed by a high energy beam after heat treatment, and then an exposed part of the photoresist film is dissolved by using an alkaline developing solution to form a positive pattern.

12. The patterning process according to claim 2, wherein the resist pattern is formed by a method that a photoresist film is formed by using a chemically amplified resist composition, the photoresist film is exposed by a high energy beam after heat treatment, and then an exposed part of the photoresist film is dissolved by using an alkaline developing solution to form a positive pattern.

13. The patterning process according to claim 1, wherein the resist pattern is formed by a method that a photoresist film is formed by using a chemically amplified resist composition, the photoresist film is exposed by a high energy beam after heat treatment, and then a unexposed part of the photoresist film is dissolved by using an organic solvent developing solution to form a negative pattern.

14. The patterning process according to claim 2, wherein the resist pattern is formed by a method that a photoresist film is formed by using a chemically amplified resist composition, the photoresist film is exposed by a high energy beam after heat treatment, and then a unexposed part of the photoresist film is dissolved by using an organic solvent developing solution to form a negative pattern.

15. The patterning process according to claim 11, wherein the lithography method using the high energy beam is a lithography method using a light having the wavelength of 300 nm or less, a lithography method using an EUV light, or an electron beam direct drawing method.

16. The patterning process according to claim 12, wherein the lithography method using the high energy beam is a lithography method using a light having the wavelength of 300 nm or less, a lithography method using an EUV light, or an electron beam direct drawing method.

17. The patterning process according to claim 13, wherein the lithography method using the high energy beam is a lithography method using a light having the wavelength of 300 nm or less, a lithography method using an EUV light, or an electron beam direct drawing method.

18. The patterning process according to claim 14, wherein the lithography method using the high energy beam is a lithography method using a light having the wavelength of 300 nm or less, a lithography method using an EUV light, or an electron beam direct drawing method.

19. The patterning process according to claim 1, wherein the counter ion shown by the general formula (A-2), (A-4), or (A-5) is an ion selected from the following ions:

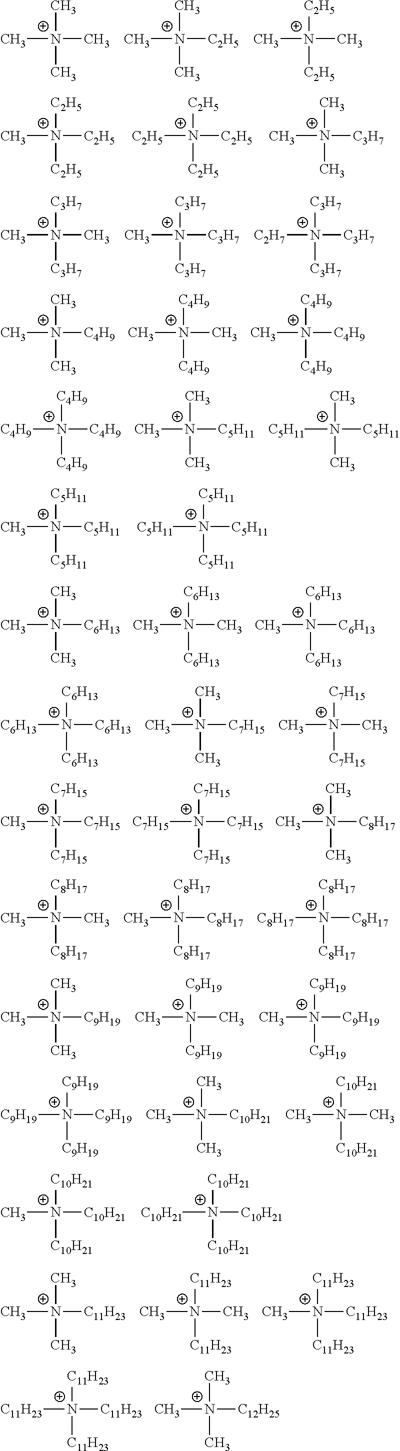

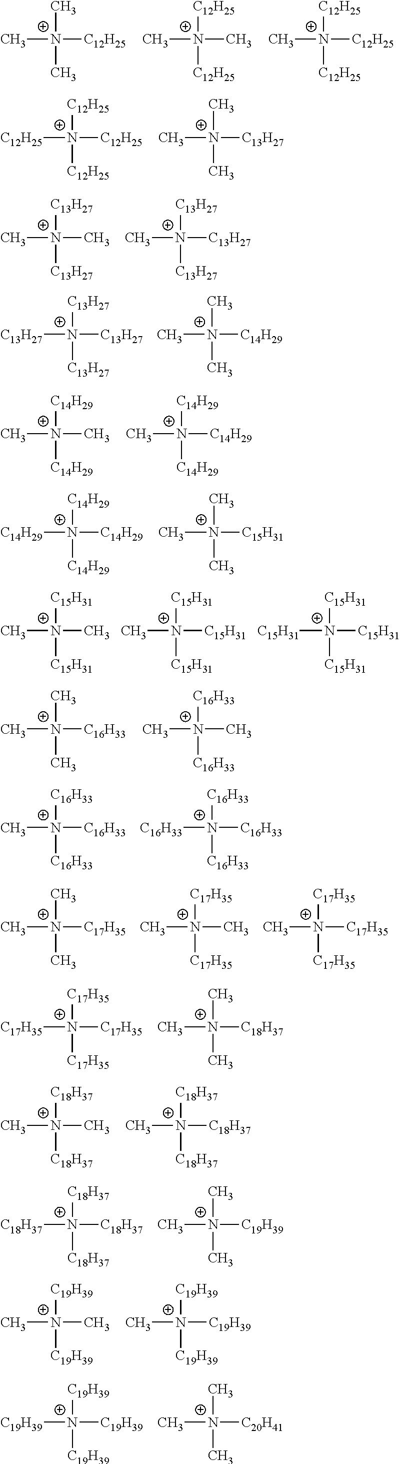

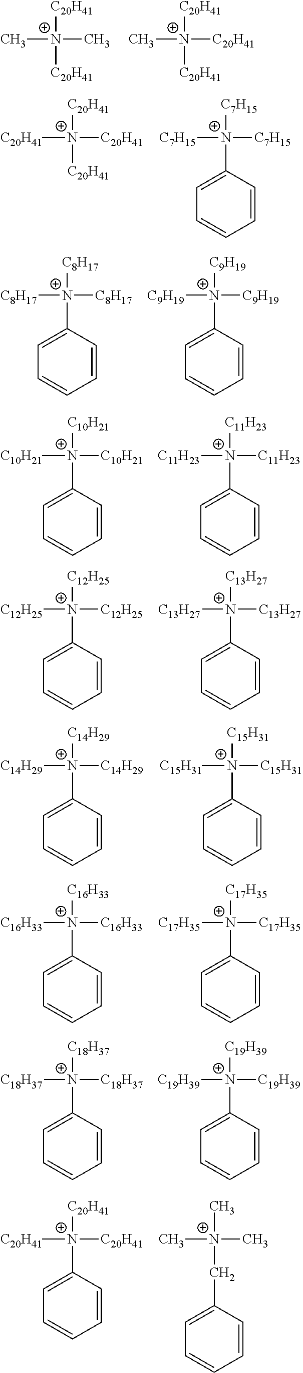

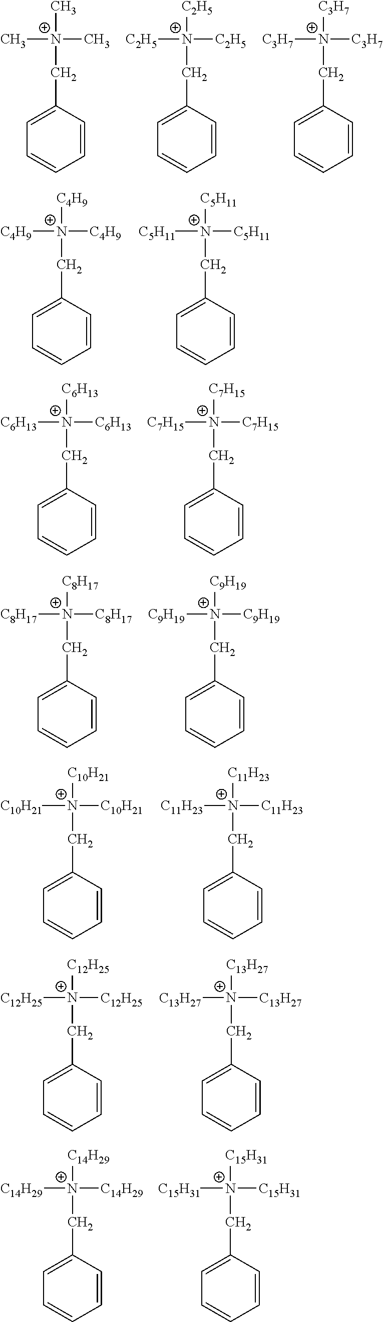

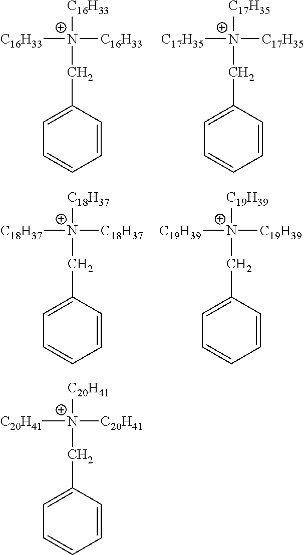

20. The patterning process according to claim 2, wherein the counter ion shown by the general formula (A-2), (A-4), or (A-5) is an ion selected from the following ions: 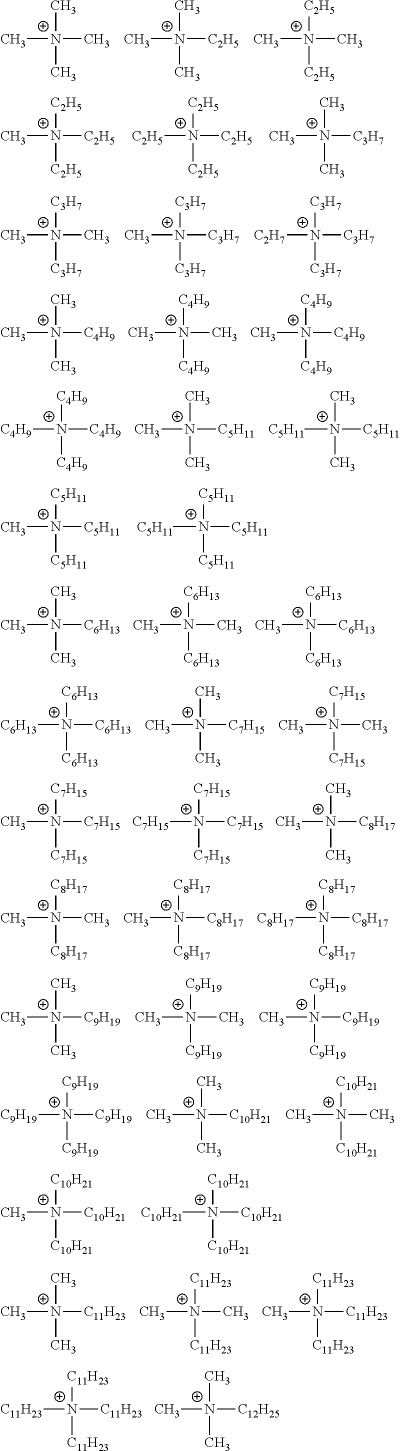 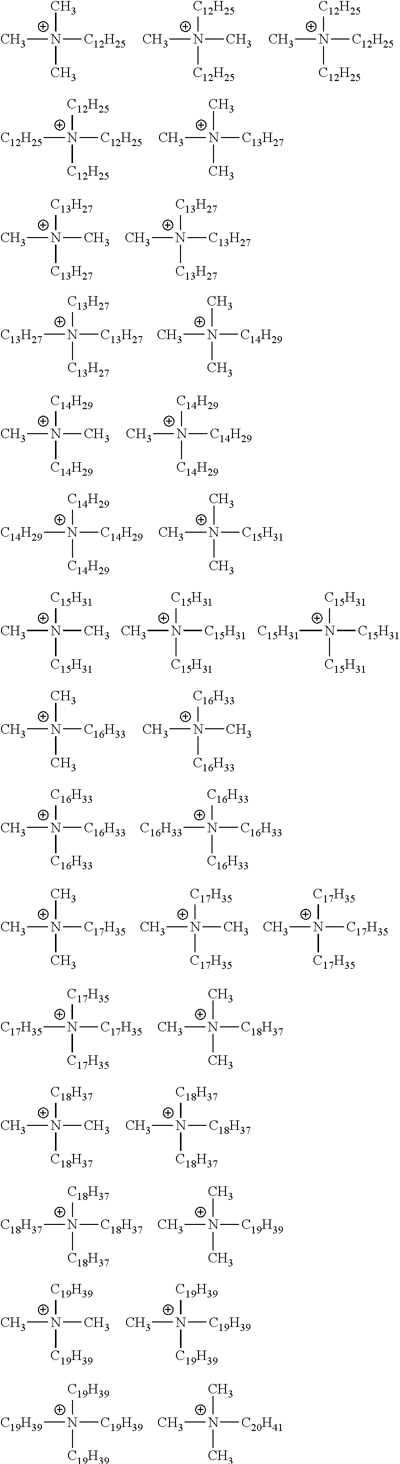 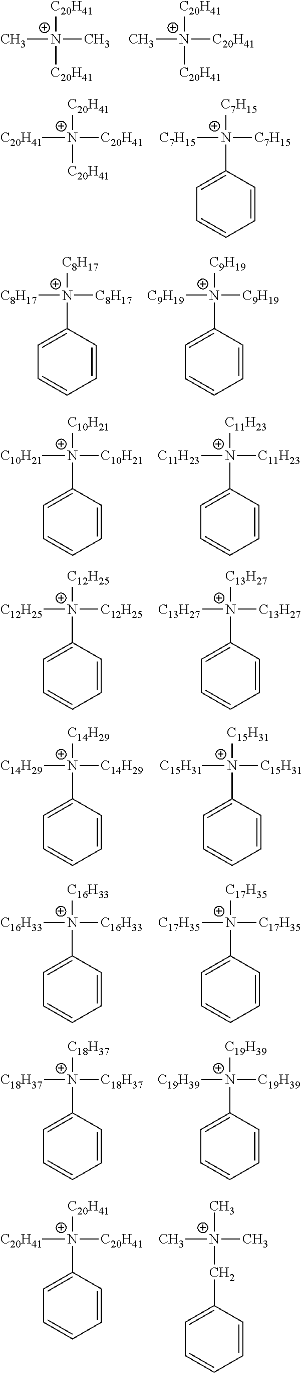 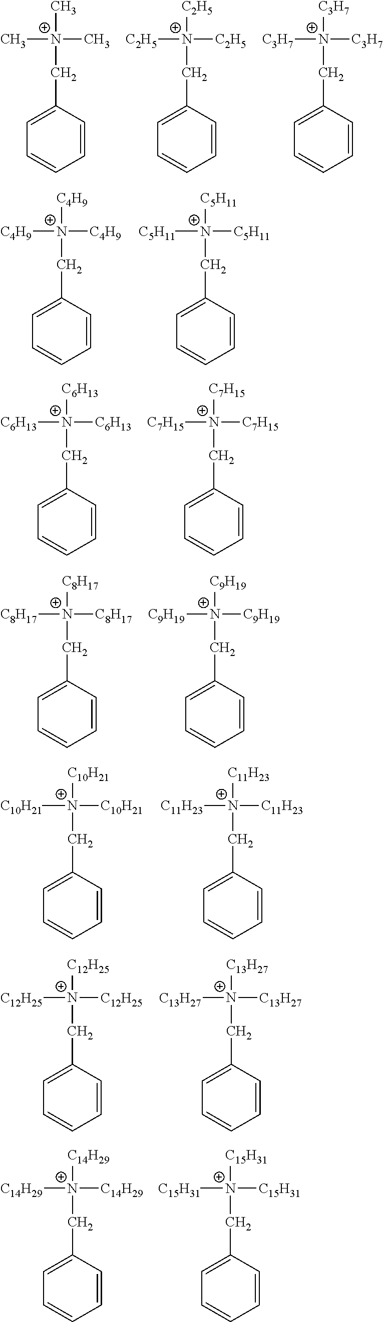 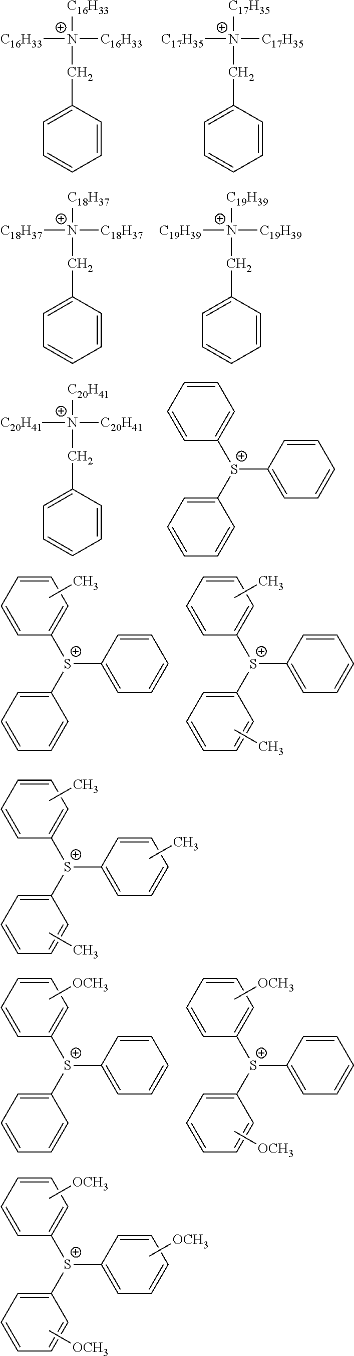 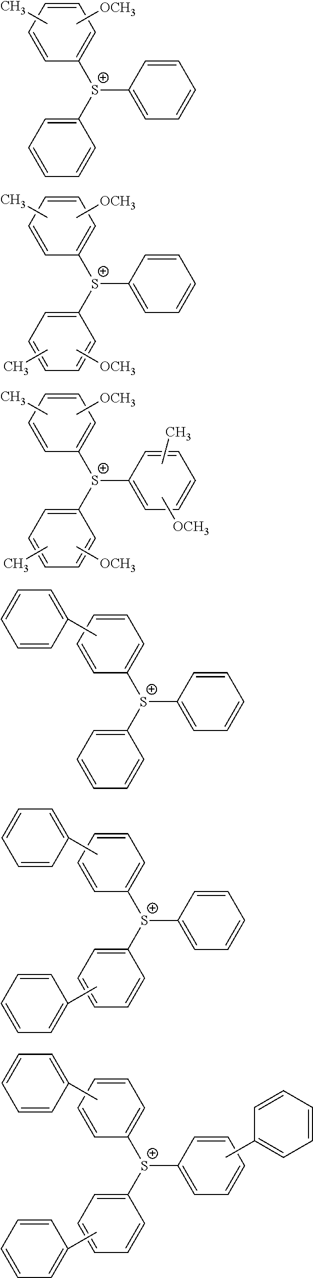 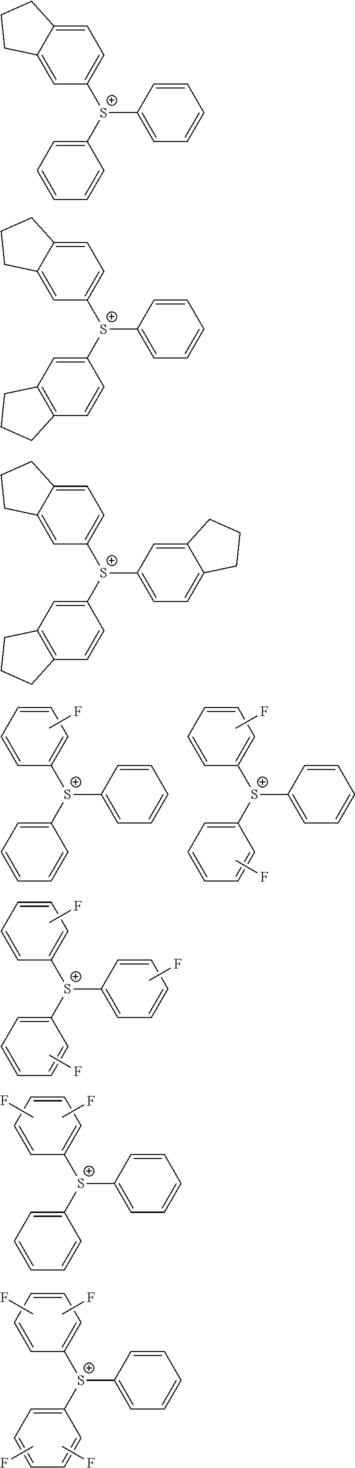 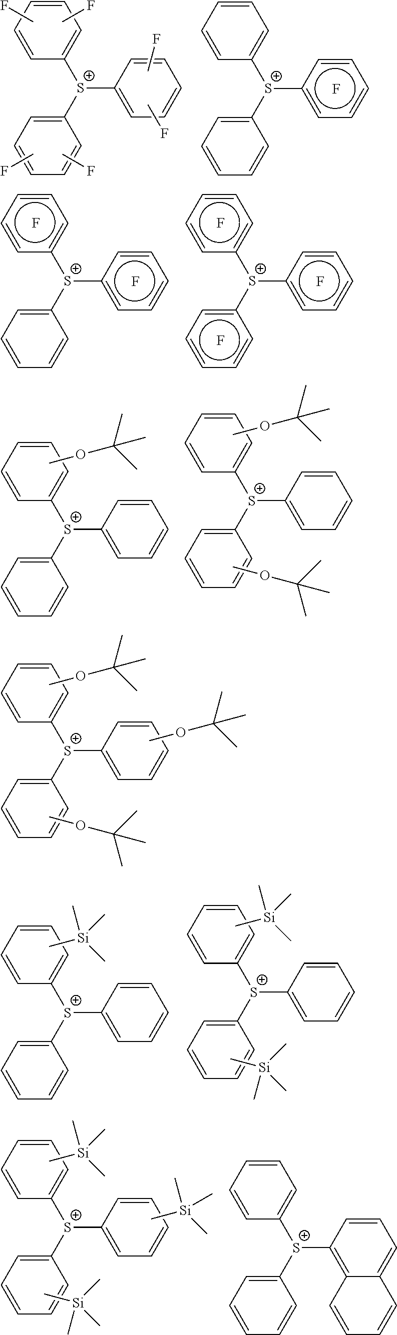 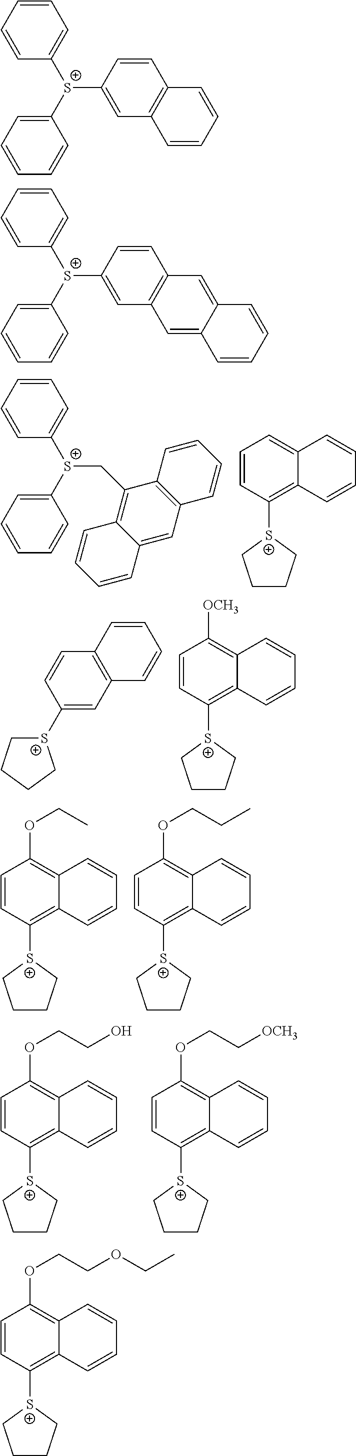 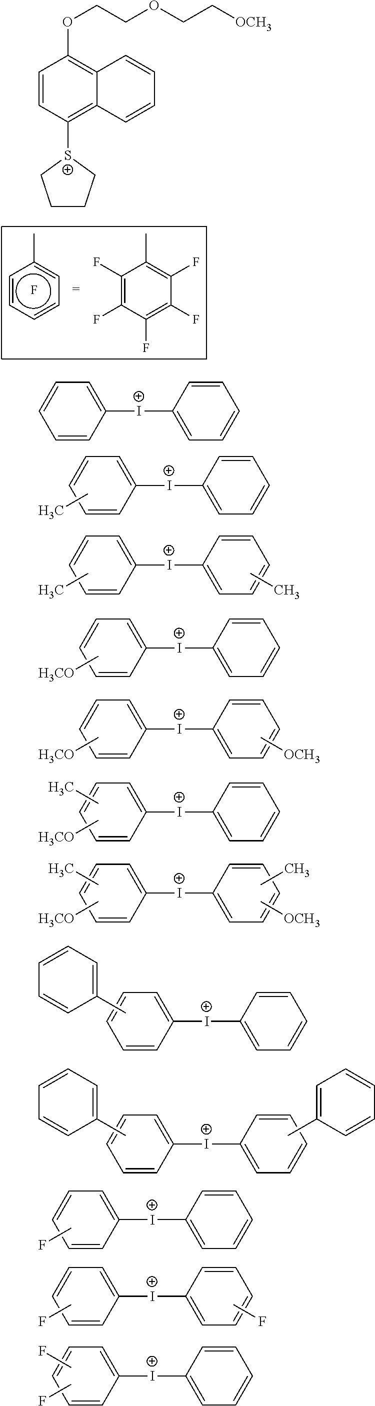 [chemical structure]
